(19) United States
(12) Patent Application Publication
(10) Pub. No.: US 2026/0356555 A1
(43) Pub. Date: Nov. 12, 2026

(54) VAPOR-DEPOSITED FILM, MULTILAYER STRUCTURE, PACKAGING MATERIAL,VACUUM PACKAGING BAG, AND VACUUM INSULATOR

(71) Applicant: Kuraray Co., Ltd., Okayama (JP)

(72) Inventors: Yasuhiro NONAKA, Kurashiki-shi, Okayama (JP); Hisashi ISHIHARA, Kurashiki-shi, Okayama (JP); Naoki KATAOKA, Osaka-shi, Osaka (JP)

(73) Assignee: Kuraray Co., Ltd., Okayama (JP)

(21) Appl. No.: 19/129,915

(22) PCT Filed: Nov. 16, 2023
(86) PCT No.: PCT/JP2023/041255

§ 371 Date: May 14, 2025

(30) Foreign Application Priority Data
Nov. 17, 2022 (JP) 2022-184440

(51) Int. Cl. B65D 65/42; B32B 1/00; B32B 27/08; B32B 27/32; B32B 27/36; B65D 65/40; B65D 81/20

(52) U.S. Cl. CPC B65D 65/42; B32B 1/00; B32B 27/08; B32B 27/32; B32B 27/36; B65D 65/40; B65D 81/2023; B32B 2255/10; B32B 2255/205; B32B 2307/518; B32B 2307/7246; B32B 2307/7376; B32B 2439/06

(57) ABSTRACT

The present disclosure provides a vapor-deposited film including a barrier layer (A) made of a resin; and a vapor-deposited aluminum layer (B).

### TECHNICAL FIELD

The present invention relates to a vapor-deposited film, a multilayer structure, a packaging material, a vacuum packaging bag, and a vacuum insulator.

### DISCUSSION OF THE BACKGROUND

A vapor-deposited film in which a vapor-deposited metal layer is provided on a base film made of a resin is known. Such a vapor-deposited film is used for a variety of applications such as a vacuum packaging bag for a vacuum insulator which is required to have gas barrier properties to maintain heat insulation performance, a packaging material for protecting an item (e.g., food) which is likely to be deteriorated by oxygen, and the like. Patent Document 1 discloses a vapor-deposited film including: a base film containing a polyvinyl alcohol polymer; and a vapor-deposited metal layer laminated on the base film, characterized in that an average particle size of the vapor-deposited metal layer measured with an electron microscope is 150 nm or less.

### PRIOR ART DOCUMENT

### Patent Document

Patent Document 1: PCT International Patent Application, Publication No. 2013/125564

### SUMMARY OF THE INVENTION

### Problems to be Solved by the Invention

In a case in which a packaging material or the like having a predetermined shape is produced from a vapor-deposited film, typically, the packaging material is prepared through a process including bending or the like. Furthermore, the prepared packaging material or the like may be bent during transportation, use, etc. However, the conventional vapor-deposited film cannot maintain sufficient gas barrier properties after receiving physical stress, especially bending. Furthermore, the gas barrier properties of the conventional vapor-deposited film tend to deteriorate after storage for a long period of time.

The present invention has been made in view of the foregoing circumstances, and an objective thereof is to provide: a vapor-deposited film in which deterioration in gas barrier properties after bending treatment and after storage is inhibited; and a multilayer structure, a packaging material, a vacuum packaging bag, and a vacuum insulator in which such a vapor-deposited film is used.

### Means for Solving the Problems

The above objective can be achieved by proving any of the following:
(1) a vapor-deposited film including: a barrier layer (A) made of a resin; and a vapor-deposited aluminum layer (B) directly laminated on the barrier layer (A) and having an average thickness of 30 nm or more and 100 nm or less, wherein the vapor-deposited aluminum layer (B) includes an aluminum oxide layer (B1) and an aluminum layer (B2) sequentially arranged in this order from a face in contact with the barrier layer (A), in an elemental analysis in a depth direction of the aluminum oxide layer (B1), a maximum value (O/Al)_{MAX} of a molar ratio of an oxygen element to an aluminum element, the molar ratio being measured using a scanning x-ray photoelectron spectrometer, is 0.5 or more and 2.0 or less, and in a depth-direction analysis of the aluminum layer (B2), a minimum value (O/Al)_{MIN} of a molar ratio of an oxygen element to an aluminum element, the molar ratio being measured using a scanning x-ray photoelectron spectrometer, is less than 0.5;
(2) the vapor-deposited film according to (1), wherein the vapor-deposited aluminum layer (B) includes an aluminum oxide layer (B3) including a face(S) opposite to the face in contact with the barrier layer (A), and in an elemental analysis of the face(S), a molar ratio (O/Al) s of an oxygen element to an aluminum element, the molar ratio being measured using a scanning x-ray photoelectron spectrometer, is 0.5 or more and 2.0 or less;
(3) the vapor-deposited film according to (1) or (2), wherein the barrier layer (A) contains, as a principal component, at least one selected from the group consisting of a vinyl alcohol polymer and a polyester resin;
(4) the vapor-deposited film according to any one of (1) to (3), wherein the barrier layer (A) is biaxially oriented;
(5) the vapor-deposited film according to any one of (1) to (4), wherein an average thickness of the barrier layer (A) is 0.1 μm or more and 20 μm or less;
(6) the vapor-deposited film according to any one of (1) to (5), wherein an average thickness of the vapor-deposited aluminum layer (B) is 55 nm or more and 90 nm or less;
(7) the vapor-deposited film according to any one of (1) to (6), further including a polyolefin layer (D) laminated on a face of the barrier layer (A) with an adhesive resin layer (C) interposed therebetween, the face being opposite to the vapor-deposited aluminum layer (B);
(8) the vapor-deposited film according to (7), wherein the barrier layer (A), the adhesive resin layer (C), and the polyolefin layer (D) are at least uniaxially oriented;
(9) a multilayer structure including: the vapor-deposited film according to (7) or (8); and a polyolefin layer (E) laminated on at least one face of the vapor-deposited film directly or with another layer interposed therebetween;
(10) the multilayer structure according to (9), wherein polyolefin layers (E) are respectively laminated on both faces of the vapor-deposited film directly or with another layer interposed therebetween, and the polyolefin layers (E) contain the same type of resin as a principal component;
(11) the multilayer structure according to (9) or (10), wherein a thickness percentage of the barrier layer (A) with respect to a total thickness of the multilayer structure is 5% or less;
(12) a multilayer structure including: the vapor-deposited film according to any one of (1) to (6); and a polyolefin layer (E) laminated on the vapor-deposited film directly or with another layer interposed therebetween;
(13) the multilayer structure according to (12), further including an other vapor-deposited film laminated on the vapor-deposited film directly or with another layer interposed therebetween, wherein the other vapor-deposited film includes: a barrier layer (a) made of a resin; and a vapor-deposited aluminum layer (b) directly laminated on the barrier layer (a) and having an average thickness of 30 nm or more and 100 nm or less;
(14) the multilayer structure according to (13), wherein the vapor-deposited aluminum layer (b) includes an aluminum oxide layer (b1) and an aluminum layer (b2) sequentially arranged in this order from a face in contact with the barrier layer (a), in an elemental analysis in a depth direction of the aluminum oxide layer (b1), a maximum value (O/Al)_{MAX} of a molar ratio of an oxygen element to an aluminum element, the molar ratio being measured using a scanning x-ray photoelectron spectrometer, is 0.5 or more and 2.0 or less, and in a depth-direction analysis of the aluminum layer (b2), a minimum value (O/Al)_{MIN} of a molar ratio of an oxygen element to an aluminum element, the molar ratio being measured using a scanning x-ray photoelectron spectrometer, is less than 0.5;
(15) the multilayer structure according to any one of (12) to (14), further including a polyamide layer (F) laminated on the vapor-deposited film directly or with another layer interposed therebetween;
(16) a packaging material including the vapor-deposited film according to any one of (1) to (8) or the multilayer structure according to any one of (9) to (15);
(17) a vacuum packaging bag including a packaging bag formed from the packaging material according to (16), wherein an inside of the packaging bag has a reduced pressure; and
(18) a vacuum insulator including: the vacuum packaging bag according to (17); and a core material disposed inside the vacuum packaging bag.

### Effects of the Invention

According to the present invention, a vapor-deposited film in which deterioration in gas barrier properties after bending treatment and after storage is inhibited; and a multilayer structure, a packaging material, a vacuum packaging bag, and a vacuum insulator in which such a vapor-deposited film is used can be provided.

### BRIEF DESCRIPTION OF THE DRAWING

FIG. 1 is a schematic cross-sectional view of a vapor-deposited film according to one embodiment of the present invention.

### DESCRIPTION OF EMBODIMENTS

As referred to herein, the “gas barrier properties” mainly mean oxygen barrier properties. A property of inhibiting deterioration in gas barrier properties after bending treatment may be expressed as “bending resistance.” Furthermore, a property of inhibiting deterioration in gas barrier properties after storage may be expressed as “storage stability.” A “principal component” refers to a component having the highest content on a mass basis.

An “average thickness” refers to an average value of thicknesses measured at five arbitrary points.

Furthermore, in an expression of a layer configuration in this specification, “/” indicates that layers are directly laminated, and “//” indicates that layers are directly laminated or laminated with an adhesive layer interposed therebetween.

The term “topmost layer” is not used to distinguish the front side and the rear side and is not limited to a layer on the front side. That is to say, a vapor-deposited film or a multilayer structure consisting of two or more layers has two topmost layers, namely a topmost layer on one face side and a topmost layer on the other face side. Furthermore, in a case of a structure in which the inside and the outside are distinguished from each other, such as a bag shape or a container shape, an inner topmost layer may be referred to as an innermost layer, and an outer topmost layer may be referred to as an outermost layer.

### Vapor-Deposited Film

A vapor-deposited film of the present invention includes: a barrier layer (A) made of a resin; and a vapor-deposited aluminum layer (B) directly laminated on the barrier layer (A) and having an average thickness of 30 nm or more and 100 nm or less, wherein the vapor-deposited aluminum layer (B) includes an aluminum oxide layer (B1) and an aluminum layer (B2) sequentially arranged in this order from a face in contact with the barrier layer (A), in an elemental analysis in a depth direction of the aluminum oxide layer (B1), a maximum value (O/A1)_{MAX} of a molar ratio of an oxygen element to an aluminum element, the molar ratio being measured using a scanning x-ray photoelectron spectrometer, is 0.5 or more and 2.0 or less, and in a depth-direction analysis of the aluminum layer (B2), a minimum value (O/A1)_{MIN} of a molar ratio of an oxygen element to an aluminum element, the molar ratio being measured using a scanning x-ray photoelectron spectrometer, is less than 0.5.

The vapor-deposited film of the present invention is superior in bending resistance and storage stability. Although the reason for this is not certain, the following reason is presumed. In the vapor-deposited film, owing to the fact that a region which is in the vapor-deposited aluminum layer (B) and in contact with the barrier layer (A) is the aluminum oxide layer (B1), the adhesion strength between the barrier layer (A) and the vapor-deposited aluminum layer (B) is increased. Accordingly, for example, even in a case in which bending treatment is performed or in a case in which a dimensional change occurs during storage, the state in which the vapor-deposited aluminum layer (B) is tightly adhered to the barrier layer (A) is maintained. Therefore, it is assumed that in the vapor-deposited film, deterioration in gas barrier properties after bending treatment and after storage is inhibited. Furthermore, in a case in which food or the like is packaged using the vapor-deposited film and stored, a decrease in the adhesiveness between the barrier layer (A) and the vapor-deposited aluminum layer (B) due to a component or the like contained in the contents such as food or the like is also inhibited. A portion of the vapor-deposited aluminum layer (B) which is peeled from the barrier layer (A) becomes bleached and causes deterioration in appearance. Therefore, in a packaging material in which the vapor-deposited film is used, both deterioration in gas barrier properties after storage and deterioration in appearance are inhibited. Moreover, in the case in which food or the like is packaged using the vapor-deposited film and stored, a phenomenon in which the vapor-deposited aluminum layer (B) is rapidly oxidized owing to a component or the like contained in the contents such as food or the like to become bleached or transparent, and deterioration in gas barrier properties due to corrosion of the aluminum oxide layer (B1) can be inhibited. Owing to the existence of the aluminum oxide layer (B1) oxidized at a certain percentage, the rapid oxidation of the aluminum layer (B2) and the corrosion of the aluminum oxide layer (B1) can be inhibited; therefore, both deterioration in gas barrier properties after storage and deterioration in appearance are inhibited.

### Barrier Layer (A)

The barrier layer (A) is a layer made of a resin. The barrier layer (A) may be a base layer for the vapor-deposited aluminum layer (B) formed by vapor deposition. The barrier layer (A) may be a layer containing the resin as a principal component. The resin which constitutes the barrier layer (A) is preferably a thermoplastic resin.

As the resin which is the principal component of the barrier layer (A), a resin having high gas barrier properties is suitably used. For example, in a case in which an unoriented film consisting of only the resin is produced, the resin preferably allows the film to have an oxygen transmission rate of 100 mL·20 μm/(m²·day·atm) or less, more preferably 50 mL·20 μm/(m²·day·atm) or less, and still more preferably 10 mL·20 μm/(m²·day·atm) or less. As referred to herein, the oxygen transmission rate is a value measured according to the method disclosed in ISO14663-2 Annex C (1999) under conditions involving 20 °C and 65% RH. For example, an oxygen transmission rate of “50 mL·20 μm/(m²·day·atm)” means that 1 m² of a film transmits 50 mL of oxygen per day at a pressure difference of an oxygen gas of one atmosphere when the film thickness is converted to an average thickness of 20 μm.

Examples of the resin which is the principal component of the barrier layer (A) include a vinyl alcohol polymer, a polyester resin, polyamide, polyvinylidene chloride, an acrylonitrile copolymer, polyvinylidene fluoride, polychlorotrifluoroethylene, and the like; at least one selected from the group consisting of a vinyl alcohol polymer and a polyester resin is preferred, and a vinyl alcohol polymer is more preferred. By using such a resin as the principal component of the barrier layer (A), the gas barrier properties can be improved, and furthermore, deterioration in gas barrier properties after bending treatment and after storage can be further inhibited. One type or two or more types of resins may be used as the resin which constitutes the barrier layer (A).

The polyester resin is a polymer having an ester bond. The polyester resin can be obtained by polycondensation or the like between a multivalent carboxylic acid and a polyol. Examples of the polyester resin include polyethylene terephthalate (PET), polyethylene naphthalate (PEN), polyglycolic acid (PGA), aromatic liquid crystalline polyester, and the like, and PET is preferred.

The vinyl alcohol polymer is a polymer containing a vinyl alcohol unit. The vinyl alcohol polymer is obtained, for example, by saponifying a vinyl ester homopolymer or a copolymer of vinyl ester and an other monomer by using an alkali catalyst or the like. Examples of the vinyl ester include vinyl acetate, vinyl propionate, vinyl pivalate, and the like, and vinyl acetate is preferred. Examples of the other monomer include ethylene; α-olefins such as propylene, butylene, isobutene, 4-methyl-1-pentene, 1-hexene, and 1-octene; unsaturated carboxylic acids such as (meth)acrylic acid or ester thereof; vinylsilane compounds such as vinyltrimethoxysilane; unsaturated sulfonic acids or salts thereof; vinyl pyrrolidone compounds such as N-vinyl pyrrolidone; and the like. Of these, ethylene is preferred. The vinyl alcohol polymer can be produced by a known method. A chain transfer agent may be used in the production. Examples of the chain transfer agent include alkylthiols and the like.

A degree of saponification of the vinyl alcohol polymer (proportion (mol %) of the vinyl alcohol unit with respect to the sum of the vinyl alcohol unit and a vinyl ester unit) is preferably 90 mol % or more, more preferably 95 mol % or more, and still more preferably 99 mol % or more. When the degree of saponification is greater than or equal to the upper limit, the gas barrier properties of the vapor-deposited film at high humidity tend to be improved. The upper limit of the degree of saponification of the vinyl alcohol polymer may be 100 mol %. The degree of saponification of the vinyl alcohol polymer can be determined by nuclear magnetic resonance (NMR) spectrometry.

A content of the vinyl alcohol unit with respect to all structural units in the vinyl alcohol polymer is preferably 30 mol % or more and 100 mol % or less, more preferably 35 mol % or more and 90 mol % or less, still more preferably 40 mol % or more and 80 mol % or less, and even still more preferably 45 mol % or more and 75 mol % or less.

The vinyl alcohol polymer is preferably an ethylene-vinyl alcohol copolymer (hereinafter, may be also referred to as “EVOH”). A content of an ethylene unit with respect to all structural units in the EVOH is preferably 10 mol % or more and 65 mol % or less, preferably 20 mol % or more and 60 mol % or less, and still more preferably 25 mol % or more and 55 mol % or less.

The EVOH may contain an other structural unit other than the vinyl alcohol unit, the ethylene unit, and the vinyl ester unit. In the case in which the EVOH contains the other structural unit, a content of the other structural unit with respect to all structural units in the EVOH is preferably 30 mol % or less, more preferably 20 mol % or less, still more preferably 10 mol % or less, even still more preferably 5 mol % or less, and may be particularly preferably 1 mol % or less. Furthermore, in the case in which the EVOH contains the other structural unit, the content thereof may be 0.05 mol % or more or may be 0.1 mol % or more.

An MFR (190 °C, load of 2.16 kg) of the EVOH is preferably 0.5 g/10 min or more and 12 g/10 min or less, and more preferably 1.0 g/10 min or more and 8.0 g/10 min or less.

In light of the gas barrier properties and the like, the lower limit of a content of the resin in the barrier layer (A) is preferably 70% by mass, more preferably 80% by mass, still more preferably 90% by mass, and may be 95% by mass, 99% by mass, or 99.9% by mass. The upper limit of the content of the resin in the barrier layer (A) may be 100% by mass or 99.99% by mass.

The barrier layer (A) may contain inorganic oxide particles. An inorganic oxide constituting the inorganic oxide particles is not particularly limited, and examples thereof include silicon oxide, aluminum oxide, magnesium oxide, zirconium oxide, cerium oxide, tungsten oxide, molybdenum oxide, complexes thereof, and the like. Of these, silicon oxide or silicon oxide-magnesium oxide is preferred, and silicon oxide is more preferred.

The lower limit of a content of the inorganic oxide particles in the barrier layer (A) is preferably 0.001% by mass, more preferably 0.005% by mass, and still more preferably 0.01% by mass. Furthermore, the upper limit of the content of the inorganic oxide particles is preferably 1% by mass, more preferably 0.7% by mass, and still more preferably 0.5% by mass. When the content of the inorganic oxide particles falls within the above range, the gas barrier properties tend to be further improved.

An average particle size of the inorganic oxide particles is preferably 1 μm or more and 10 μm or less, and more preferably 2 μm or more and 5 μm or less. When the average particle size of the inorganic oxide particles falls within the above range, the gas barrier properties tend to be further improved. The average particle size of the inorganic oxide particles is a value measured by a laser diffraction scattering method.

The barrier layer (A) may further contain a boron compound, a carboxylic acid, a phosphorus compound, a metal ion, an antioxidant, an ultraviolet absorbing agent, a plasticizer, an antistatic agent, a lubricant, a coloring agent, a filler, a thermal stabilizer, or the like. The barrier layer (A) may contain two or more types of these optional components.

The barrier layer (A) may be an unoriented layer or an oriented layer. The barrier layer (A) may be uniaxially oriented or biaxially oriented. In the case in which the barrier layer (A) is an oriented layer, especially a biaxially oriented layer, even the barrier layer (A) which is relatively thin can exert favorable gas barrier properties.

In the case in which the barrier layer (A) is an oriented layer, for example, the barrier layer (A) is preferably at least uniaxially oriented by 2 times or more and less than 12 times, and more preferably at least uniaxially oriented by 3 times or more and less than 6 times. Furthermore, the barrier layer (A) is also preferably biaxially oriented by 2 times or more and less than 12 times in each direction, and more preferably biaxially oriented by 3 times or more and less than 6 times in each direction.

The lower limit of an average thickness of the barrier layer (A) is preferably 0.1 μm, more preferably 0.5 μm, still more preferably 1 μm, and may be 2 μm, 4 μm, or 6 μm. When the average thickness of the barrier layer (A) is greater than or equal to the lower limit, for example, the gas barrier properties can be improved. The upper limit of the average thickness of the barrier layer (A) is preferably 20 μm, more preferably 15 μm, and may be 10 μm, 5 μm, 3 μm, or 2 μm. When the average thickness of the barrier layer (A) is less than or equal to the upper limit, for example, the vapor-deposited film can be reduced in thickness and weight.

An oxygen transmission rate of the barrier layer (A) is preferably 50 mL·20 μm/(m²·day·atm) or less, more preferably 10 mL·20 μm/(m² day·atm) or less, still more preferably 5 mL·20 μm/(m² day·atm) or less, and particularly preferably 1 mL·20 μm/(m² day·atm) or less. As referred to herein, the oxygen transmission rate is a value measured according to the method disclosed in ISO14663-2 Annex C (1999) under conditions involving 20 °C and 65% RH.

The barrier layer (A) may consist of a single layer or a plurality of layers.

As the barrier layer (A), a resin film may be used. A method for producing the resin film including the barrier layer (A) is not particularly limited; examples thereof include a fusion method, a solution method, a calender method, and the like, and of these, a fusion method is preferred. Examples of the fusion method include a casting method and an inflation method, and of these, a casting method is preferred. Furthermore, an oriented film oriented by a known method may also be used.

### Vapor-Deposited Aluminum Layer (B)

The vapor-deposited aluminum layer (B) is a layer directly laminated on a surface of the barrier layer (A) by vapor deposition. When the vapor-deposited aluminum layer (B) is provided in the vapor-deposited film, favorable gas barrier properties can be exerted.

The vapor-deposited aluminum layer (B) includes the aluminum oxide layer (B1) and the aluminum layer (B2) sequentially arranged in this order from the face in contact with the barrier layer (A). The vapor-deposited aluminum layer (B) preferably further includes an aluminum oxide layer (B3) including a face(S) opposite to the face in contact with the barrier layer (A).

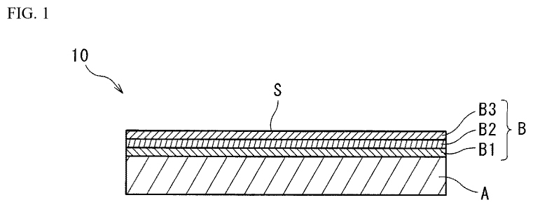

FIG. 1 shows a vapor-deposited film 10 according to one embodiment of the present invention. The vapor-deposited film 10 includes: the barrier layer (A) made of the resin; and the vapor-deposited aluminum layer (B) directly laminated on the barrier layer (A). The vapor-deposited aluminum layer (B) has a three-layer structure including the aluminum oxide layer (B1), the aluminum layer (B2), and the aluminum oxide layer (B3) in this order from the face in contact with the barrier layer (A). The structure of the vapor-deposited film of the present invention is not limited to the structure of the vapor-deposited film 10 in FIG. 1. The vapor-deposited film of the present invention may include an adhesive resin layer (C), a polyolefin layer (D), and other layer(s) described later. Furthermore, the vapor-deposited film may include an other layer which covers the face(S) of the vapor-deposited aluminum layer (B), the face(S) being opposite to the face in contact with the barrier layer (A). As in the vapor-deposited film 10 in FIG. 1, the face(S) of the vapor-deposited aluminum layer (B) may be uncovered, i.e., exposed.

The other layer which covers the face(S) is exemplified by an overcoat layer. The overcoat layer can be provided, for example, by coating with a solution containing a solvent-soluble or water-soluble resin (a polyester resin, an acrylic resin, a vinyl alcohol resin, an ethylene vinyl alcohol copolymer (EVOH) resin, a vinyl-modified resin, an epoxy resin, an oxazoline group-containing resin, a modified styrene resin, a modified silicone resin, alkyl titanate, etc.). A filler may be added to the overcoat layer to improve the barrier properties, the abrasion resistance, the slipperiness, and the like. Examples of the filler include a silica sol, an alumina sol, a particulate inorganic filler, a layered inorganic filler, and the like. The overcoat layer is preferably formed in such a manner that the filler is added to the above-mentioned resin and polymerization or condensation is performed. The other layer which covers the face(S) may be a thermoplastic resin layer formed by a method other than coating with a solution, any of layers used in a multilayer structure described later, or the like.

No clear interface exists between the aluminum oxide layer (B1) and the aluminum layer (B2) or between the aluminum layer (B2) and the aluminum oxide layer (B3). Furthermore, in each of the aluminum oxide layer (B1), the aluminum layer (B2), and the aluminum oxide layer (B3), typically, the elementary composition is not constant. The content percentage of an oxygen element gradually decreases from the aluminum oxide layer (B1) to the aluminum layer (B2). Furthermore, the content percentage of an oxygen element gradually increases from the aluminum layer (B2) to the aluminum oxide layer (B3). In other words, in the vapor-deposited aluminum layer (B), the content percentage of an oxygen element in an intermediate layer portion (aluminum layer (B2)) is relatively low. Furthermore, in the vapor-deposited aluminum layer (B), a region having a predetermined thickness from the face in contact with the barrier layer (A) (aluminum oxide layer (B1)) and a region having a predetermined thickness from the face(S) opposite to the face in contact with the barrier layer (A) (aluminum oxide layer (B3)) have high content percentages of an oxygen element relative to the intermediate layer portion (aluminum layer (B2)).

In the elemental analysis in the depth direction of the aluminum oxide layer (B1), the maximum value (O/Al)_{MAX} of the molar ratio of an oxygen element to an aluminum element, the molar ratio being measured using a scanning x-ray photoelectron spectrometer, is 0.5 or more and 2.0 or less, preferably 0.8 or more and 1.8 or less, and more preferably 1.1 or more and 1.5 or less. When the maximum value (O/Al)_{MAX} of the molar ratio of an oxygen element to an aluminum element in the aluminum oxide layer (B1) falls within the above range, the adhesiveness of the vapor-deposited aluminum layer (B) with respect to the barrier layer (A) can be increased, and thus, the bending resistance and the storage stability of the vapor-deposited film can be improved.

In the elemental analysis in the depth direction of the aluminum oxide layer (B1), a position at which the maximum value (O/Al)_{MAX} of the molar ratio of an oxygen element to an aluminum element is observed is preferably present within a range of 0 nm or more and 20 nm or less, more preferably within a range of 0 nm or more and 15 nm or less, from the face in contact with the barrier layer (A).

In the depth-direction analysis of the aluminum layer (B2), the minimum value (O/A1)_{MIN} of the molar ratio of an oxygen element to an aluminum element, the molar ratio being measured using a scanning x-ray photoelectron spectrometer, is less than 0.5, preferably 0.001 or more and less than 0.5, more preferably 0.003 or more and less than 0.2, still more preferably 0.005 or more and less than 0.10, and even still more preferably 0.01 or more and less than 0.06. When the minimum value (O/Al)_{MIN} of the molar ratio of an oxygen element (O) to an aluminum element (Al) in the aluminum layer (B2) falls within the above range, the gas barrier properties, the bending resistance, the storage stability, and the like of the vapor-deposited film tend to be improved.

In an elemental analysis of the face(S) of the vapor-deposited aluminum layer (B), the face(S) being opposite to the face in contact with the barrier layer (A), a molar ratio (O/Al) s of an oxygen element to an aluminum element, the molar ratio being measured using a scanning x-ray photoelectron spectrometer, is preferably 0.5 or more and 2.0 or less, more preferably 0.8 or more and 1.8 or less, and still more preferably 1.1 or more and 1.7 or less. When the molar ratio (O/Al) s of an oxygen element to an aluminum element in the face(S) of the vapor-deposited aluminum layer (B) falls within the above range, the bending resistance, the storage stability, and the like tend to be further improved.

The maximum value (O/Al)_{MAX} of the molar ratio of an oxygen element to an aluminum element in the aluminum oxide layer (B1) may be larger than the molar ratio (O/Al) s of an oxygen element to an aluminum element in the face(S) of the vapor-deposited aluminum layer (B), and vice versa. That is to say, the maximum value (O/A1)_{MAX} of the molar ratio of an oxygen element to an aluminum element in the aluminum oxide layer (B1) is the maximum value in the aluminum oxide layer (B1) and does not necessarily coincide with the maximum value in the vapor-deposited aluminum layer (B). Furthermore, besides the face(S), the aluminum oxide layer (B3) may include a portion in which the molar ratio (O/Al) of an oxygen element to an aluminum element is higher than the value of (O/Al)_{MAX} or (O/Al) s.

An average thickness of the vapor-deposited aluminum layer (B) is 30 nm or more and 100 nm or less. The lower limit of the average thickness of the vapor-deposited aluminum layer (B) is preferably 35 nm, more preferably 45 nm, still more preferably 55 nm, and even still more preferably 65 nm. When the average thickness of the vapor-deposited aluminum layer (B) is greater than or equal to the lower limit, the gas barrier properties, the bending resistance, the storage stability, and the like of the vapor-deposited film can be further improved. The upper limit of the average thickness of the vapor-deposited aluminum layer (B) is preferably 90 nm and may be 80 nm, 70 nm, or 60 nm.

The vapor-deposited aluminum layer (B) can be effectively provided, for example, by a vacuum deposition method. For example, at the time of performing vacuum deposition of aluminum on a resin film to be the barrier layer (A) while transporting the resin film, the vapor deposition is performed while a small amount of an oxygen gas is supplied to the resin film immediately before the vapor deposition. Consequently, an aluminum element in the form of aluminum oxide is laminated on a surface of the resin film (barrier layer (A)) to form the aluminum oxide layer (B1). The maximum value (O/Al)_{MAX} of the molar ratio of an oxygen element (O) to an aluminum element (Al) in the aluminum oxide layer (B1) can be controlled by the supply amount of the oxygen gas blown onto the resin film. The supply amount of the oxygen gas for the resin film may be, for example, 20 mL/min or more and 180 mL/min or less. By supplying the oxygen gas, the pressure during the vacuum deposition is lowered. The oxygen gas is preferably supplied such that the pressure during the vacuum deposition is 1.0×10⁻⁴ Pa or more and 1.0×10⁻³ Pa or less. It is to be noted that a suitable supply amount of the oxygen gas and a suitable pressure are appropriately adjusted in accordance with the deposition rate of the aluminum and the like.

It is to be noted that owing to an exposure to the air atmosphere or the like, an oxide film is typically formed on a surface of the vapor-deposited film in which the vapor-deposited aluminum layer (B) is provided by the vacuum deposition method, and this oxide film may serve as the aluminum oxide layer (B3). Furthermore, the vapor-deposited aluminum layer (B) may be provided by a vapor deposition method other than the one described above. The vapor-deposited aluminum layer (B) may be provided by a sputtering method, an ion plating method, an ion beam mixing method, a plasma CVD method, a laser CVD method, a MO-CVD method, a thermal CVD method, or the like.

Before the vapor deposition, the surface of the barrier layer (A) on which the vapor deposition is to be performed may be subjected to plasma treatment. A known method may be used as the plasma treatment, and atmospheric pressure plasma treatment is preferred. Examples of a discharge gas in the atmospheric pressure plasma treatment include a nitrogen gas, helium, neon, argon, krypton, xenon, radon, and the like.

### Adhesive Resin Layer (C)

The vapor-deposited film of the present invention preferably further includes the polyolefin layer (D) laminated on a face of the barrier layer (A) with the adhesive resin layer (C) interposed therebetween, the face being opposite to the vapor-deposited aluminum layer (B).

The adhesive resin layer (C) typically contains an adhesive resin as a principal component. The adhesive resin is not particularly limited as long as it is a resin having adhesiveness, and examples thereof include acid-modified polyolefins (a carboxylic acid-modified polyolefin, a sulfonic acid-modified polyolefin, etc.), epoxy modified polyolefins, and the like. The adhesive resin is preferably a thermoplastic resin. The adhesive resin is preferably an acid-modified polyolefin (acid-modified polyethylene, acid-modified polypropylene, etc.) and more preferably acid-modified polyethylene. Furthermore, the adhesive resin is also preferably a carboxylic acid-modified polyolefin and more preferably carboxylic acid-modified polyethylene.

The carboxylic acid-modified polyolefin may be a polyolefin having a carboxy group or an anhydride group thereof. The carboxylic acid-modified polyolefin (polyolefin having a carboxy group or an anhydride group thereof) can be obtained, for example, by chemically bonding an ethylenically unsaturated carboxylic acid or an anhydride thereof to an unmodified polyolefin by an addition reaction, a graft reaction, or the like.

The unmodified polyolefin used in the production of the carboxylic acid-modified polyolefin is preferably polyethylene or polypropylene and more preferably polyethylene.

Examples of the ethylenically unsaturated carboxylic acid and the anhydride thereof include monocarboxylic acids, monocarboxylic acid ester, dicarboxylic acids, dicarboxylic acid monoester, dicarboxylic acid diester, dicarboxylic anhydrides, and the like. Specific examples include maleic acid, fumaric acid, itaconic acid, maleic anhydride, itaconic anhydride, maleic acid monomethyl ester, maleic acid monoethyl ester, maleic acid diethyl ester, fumaric acid monomethyl ester, and the like. Of these, dicarboxylic anhydrides such as maleic anhydride, itaconic anhydride, and the like are preferred, and maleic anhydride is more preferred. That is to say, the adhesive resin is also preferably a maleic anhydride-modified polyolefin and more preferably maleic anhydride-modified polyethylene.

The carboxylic acid-modified polyolefin can be obtained, for example, by introducing the ethylenically unsaturated carboxylic acid or the anhydride thereof into the unmodified polyolefin by an addition reaction or a graft reaction in the presence of a solvent such as xylene and a catalyst such as a peroxide. At this time, the lower limit of an addition amount or a graft amount (degree of modification) of the carboxylic acid or the anhydride thereof with respect to the unmodified polyolefin is preferably 0.01% by mass and more preferably 0.02% by mass with respect to the unmodified polyolefin. On the other hand, the upper limit of the addition amount or the graft amount (degree of modification) is preferably 15% by mass and more preferably 10% by mass with respect to the unmodified polyolefin.

A content of the adhesive resin in the adhesive resin layer (C) is preferably 80% by mass or more and 100% by mass or less, more preferably 90% by mass or more and 100% by mass or less, and more preferably 97% by mass or more and 100% by mass or less. The adhesive resin layer (C) may contain, as a component other than the adhesive resin, an antioxidant, an ultraviolet absorbing agent, a plasticizer, an antistatic agent, a lubricant, a coloring agent, a filler, a thermal stabilizer, a resin other than the adhesive resin, or the like.

The adhesive resin layer (C) may be an unoriented layer or an oriented layer.

The lower limit of an average thickness of the adhesive resin layer (C) is preferably 0.1 μm, more preferably 0.5 μm, still more preferably 1 μm, and may be 2 μm. When the average thickness of the adhesive resin layer (C) is greater than or equal to the lower limit, for example, sufficient adhesiveness can be exerted. The upper limit of the average thickness of the adhesive resin layer (C) is preferably 20 μm, more preferably 10 μm, still more preferably 5 μm, and may be 3 μm. When the average thickness of the adhesive resin layer (C) is less than or equal to the upper limit, for example, the thickness of the vapor-deposited film can be reduced.

### Polyolefin Layer (D)

In the case in which the vapor-deposited film includes the polyolefin layer (D), the water vapor barrier properties, the bending resistance, the storage stability, and the like can be improved. Furthermore, in a case of a vapor-deposited film in which the polyolefin layer (D) is a topmost layer, for example, the vapor-deposited film can also be easily formed into a shape such as a bag shape or the like by heat-sealing the polyolefin layer (D) as a thermal fusion layer. In the case in which the vapor-deposited film of the present invention is formed into a bag shape, the innermost layer may be the polyolefin layer (D).

The polyolefin layer (D) contains a polyolefin as a principal component. Examples of the polyolefin include olefin homopolymers and copolymers thereof such as polyethylene (linear low-density polyethylene, low-density polyethylene, middle-density polyethylene, high-density polyethylene, etc.), ethylene-propylene copolymers, polypropylene, propylene-α-olefin (α-olefin having 4 to 20 carbon atoms) copolymers, polybutene, polypentene, and the like. Of these, polyethylene or polypropylene is preferred, and polypropylene is more preferred. One type or two or more types of polyolefins may be used.

A content of the polyolefin in the polyolefin layer (D) is preferably 80% by mass or more and 100% by mass or less, more preferably 90% by mass or more and 100% by mass or less, and more preferably 97% by mass or more and 100% by mass or less. The polyolefin layer (D) may contain, as a component other than the polyolefin, an antioxidant, an ultraviolet absorbing agent, a plasticizer, an antistatic agent, a lubricant, a coloring agent, a filler, a thermal stabilizer, a resin other than the polyolefin, or the like.

The polyolefin layer (D) may be an unoriented layer or an oriented layer.

The lower limit of an average thickness of the polyolefin layer (D) is preferably 1 μm, more preferably 5 μm, and still more preferably 10 μm. When the average thickness of the polyolefin layer (D) is greater than or equal to the lower limit, sufficient moisture barrier properties and the like can be exerted. The upper limit of the average thickness of the polyolefin layer (D) is preferably 100 μm, more preferably 50 μm, and still more preferably 30 μm. When the average thickness of the polyolefin layer (D) is less than or equal to the upper limit, for example, the thickness of the vapor-deposited film can be reduced.

The polyolefin layer (D) may consist of a single layer or a plurality of layers.

The barrier layer (A), the adhesive resin layer (C), and the polyolefin layer (D) are preferably at least uniaxially oriented and more preferably biaxially oriented. In such a case, the gas barrier properties, the bending resistance, the storage stability, and the like of the vapor-deposited film can be further improved. For example, the barrier layer (A), the adhesive resin layer (C), and the polyolefin layer (D) are preferably at least uniaxially oriented by 2 times or more and less than 12 times, and more preferably at least uniaxially oriented by 3 times or more and less than 6 times. Furthermore, the barrier layer (A), the adhesive resin layer (C), and the polyolefin layer (D) are also preferably biaxially oriented by 2 times or more and less than 12 times in each direction, and more preferably biaxially oriented by 3 times or more and less than 6 times in each direction.

The barrier layer (A), the adhesive resin layer (C), and the polyolefin layer (D) are preferably oriented in an integrated manner. For example, the barrier layer (A), the adhesive resin layer (C), and the polyolefin layer (D) may be an oriented multilayer film in which these layers are laminated in this order. Furthermore, the vapor-deposited film can be obtained by providing the vapor-deposited aluminum layer (B) by vapor deposition on a barrier layer (A)-side surface of a multilayer film in which the barrier layer (A), the adhesive resin layer (C), and the polyolefin layer (D) are laminated in this order.

A method for producing the multilayer film including the barrier layer (A), the adhesive resin layer (C), and the polyolefin layer (D) is not particularly limited, and a coextrusion method is preferred. By employing the coextrusion method, the film characteristics such as gas barrier properties and flexibility, the process passability (reduction in film thickness variation), and the economic efficiency (a target feature (for example, a reduction in the thickness of the barrier layer (A)) can be easily achieved in a small number of steps) can be well balanced at a high level. That is to say, the barrier layer (A), the adhesive resin layer (C), and the polyolefin layer (D) are preferably a coextruded film. Examples of the coextrusion method include coextrusion cast molding, coextrusion inflation molding, coextrusion coating, and the like.

The vapor-deposited film of the present invention may include other layer(s) besides the barrier layer (A), the vapor-deposited aluminum layer (B), the adhesive resin layer (C), and the polyolefin layer (D). Examples of the other layer(s) include the above-mentioned overcoat layer, another thermoplastic resin layer, another vapor-deposited layer, a paper layer, a metal foil layer, and the like. One type or two or more types of layers may be used as the other layer(s).

### Layer Configuration, Etc.

Examples of a layer configuration of the vapor-deposited film of the present invention include:
(1) A/B;
(2) D/C/A/B;
(3) X//D/C/A/B;
(4) A/B//X;
(5) D/C/A/B//X; and
(6) X//D/C/A/B//X.

It is to be noted that A denotes the barrier layer, B denotes the vapor-deposited aluminum layer, C denotes the adhesive resin layer, D denotes the polyolefin layer, and X denotes the other layer(s).

An average thickness of the vapor-deposited film of the present invention is not particularly limited, and the lower limit may be, for example, 5 μm, 10 μm, or 15 μm. On the other hand, the upper limit of the average thickness may be, for example, 200 μm, 100 μm, 50 μm, 30 μm, or 20 μm. The shape of the vapor-deposited film is not particularly limited as long as it has a laminated structure.

An oxygen transmission rate of the vapor-deposited film of the present invention is preferably less than 1.0 mL/(m²·day·atm), more preferably less than 0.10 mL/(m²·day·atm), still more preferably less than 0.05 mL/(m²·day·atm), and particularly preferably less than 0.01 mL/(m²·day·atm). When the oxygen transmission rate is less than the upper limit, the vapor-deposited film can be particularly suitably used as a variety of packaging materials and the like. On the other hand, the lower limit of the oxygen transmission rate may be 0 mL/(m²·day·atm) or 0.001 mL/(m²·day·atm). The oxygen transmission rate of the vapor-deposited film is a value measured according to the method disclosed in ISO14663-2 Annex C (1999) under conditions involving 20 °C and 65% RH.

The vapor-deposited film of the present invention is superior in bending resistance and storage stability. Furthermore, the vapor-deposited film also has favorable gas barrier properties. Therefore, the vapor-deposited film can be used for a variety of applications. Examples of the application of the vapor-deposited film include: a variety of packaging materials for food packaging, medical packaging, industrial chemical packaging, agrochemical packaging, etc.; a vacuum insulated bag; and the like.

### Multilayer Structure

The vapor-deposited film of the present invention is also suitably used as a multilayer structure including another layer further laminated thereon.

### Polyolefin Layer (E)

A multilayer structure according to one embodiment of the present invention includes: the vapor-deposited film of the present invention; and a polyolefin layer (E) laminated on at least one face of the vapor-deposited film directly or with another layer interposed therebetween. In the case in which the multilayer structure includes the polyolefin layer (E) as well as the vapor-deposited film, in addition to the gas barrier properties, the water vapor barrier properties and the like can be improved. Furthermore, in a case of a multilayer structure in which the polyolefin layer (E) is a topmost layer, for example, the multilayer structure can also be easily formed into a shape such as a bag shape or the like by heat-sealing the polyolefin layer (E) as a thermal fusion layer. In the case in which the multilayer structure of the present invention is formed into a bag shape, the innermost layer may be the polyolefin layer (E).

In the case in which the vapor-deposited film included in the multilayer structure of the present invention includes the polyolefin layer (D), the polyolefin layer (D) is one layer of the coextruded film, whereas the polyolefin layer (E) is, for example, a layer separately laminated by extrusion lamination or the like; thus, these polyolefin layers can be distinguished from each other. It is to be noted that a method for laminating the polyolefin layer (E) is not particularly limited.

The polyolefin layer (E) may be directly laminated on the vapor-deposited film of the present invention or may be laminated with an other layer interposed therebetween.

Examples of the other layer include an adhesive layer and the like. Examples of the adhesive layer include a layer in which an adhesive resin similar to that in the adhesive resin layer (C) described above is used, a layer consisting of a curable adhesive (e.g., two-component polyurethane adhesive), and the like.

A specific mode of the composition of the polyolefin layer (E) is similar to that of the polyolefin layer (D). A polyolefin which is a principal component of the polyolefin layer (E) is preferably polyethylene or polypropylene.

The polyolefin layer (E) may be an unoriented layer or an oriented layer. In the case in which the multilayer structure of the present invention is formed into a bag shape and the innermost layer is the polyolefin layer (E), in light of the fact that the heat sealing properties are favorable, the polyolefin layer (E) serving as the innermost layer is preferably an unoriented layer. In the case in which the multilayer structure of the present invention is formed into a bag shape and the outermost layer is the polyolefin layer (E), in light of the fact that the mechanical strength is favorable, the polyolefin layer (E) serving as the outermost layer is preferably oriented and more preferably biaxially oriented.

The lower limit of an average thickness of the polyolefin layer (E) is preferably 5 μm, more preferably 10 μm, still more preferably 15 μm, and may be 20 μm, 30 μm, or 40 μm. When the average thickness of the polyolefin layer (E) is greater than or equal to the lower limit, for example, sufficient moisture barrier properties can be exerted. Furthermore, in a case in which the polyolefin layer (E) is a topmost layer, when the average thickness of the polyolefin layer (E) is greater than or equal to the lower limit, sufficient heat sealing properties can also be exerted. The upper limit of the average thickness of the polyolefin layer (E) is preferably 200 μm, more preferably 100 μm, and may be 60 μm or 40 μm. When the average thickness of the polyolefin layer (E) is less than or equal to the upper limit, for example, the thickness of the multilayer structure can be reduced.

In a case in which the polyolefin layer (E) is laminated on the polyolefin layer (D), in light of inhibiting deterioration in gas barrier properties after storage, a total thickness of the polyolefin layer (D) and the polyolefin layer (E) is preferably 40 μm or more, more preferably 50 μm or more, still more preferably 55 μm or more, and particularly preferably 60 μm or more. The total thickness of the polyolefin layer (D) and the polyolefin layer (E) may be, for example, 200 μm or less.

The polyolefin layer (E) may consist of a single layer or a plurality of layers.

In the multilayer structure of the present invention, polyolefin layers (E) may be respectively laminated on both faces of the vapor-deposited film of the present invention directly or with another layer interposed therebetween. In the multilayer structure in such a mode, both of the polyolefin layers (E) may be preferably the topmost layers.

In the case in which the polyolefin layers (E) are respectively laminated on both faces of the vapor-deposited film of the present invention directly or with another layer interposed therebetween, the polyolefin layers (E) preferably contain the same type of resin as a principal component. The same type of resin means, for example, that both resins are polyethylene or that both resins are polypropylene. In the sense of the same type of resin, the resins may be different in density, melting point, whether oriented or unoriented, etc. For example, two polyolefin layers (E) may be laminated using the same material. In the case in which the two polyolefin layers (E) contain the same type of resin as a principal component, advantages such as an improvement in recyclability and the like can be obtained. For example, superior compatibility can be obtained at a time of retrieving and performing melt molding, and thus, a recycled product having good appearance can be formed.

### Other Vapor-Deposited Film

The multilayer structure of the present invention may further include an other vapor-deposited film (second vapor-deposited film) laminated on the vapor-deposited film of the present invention (first vapor-deposited film) directly or with another layer interposed therebetween. In other words, the multilayer structure of the present invention may include a plurality of vapor-deposited films, wherein at least one of the plurality of vapor-deposited films is the vapor-deposited film of the present invention. The multilayer structure including the plurality of vapor-deposited films is further superior in gas barrier properties, bending resistance, storage stability, and the like.

The plurality of vapor-deposited films may be directly laminated or may be laminated with an other layer interposed therebetween. Examples of the other layer include an adhesive layer, the polyolefin layer (E), a polyamide layer (F) described later, and the like, and an adhesive layer is preferred. A plurality of layers may be present between the plurality of vapor-deposited films.

The other vapor-deposited film (second vapor-deposited film) includes, for example: a barrier layer (a) made of a resin; and a vapor-deposited aluminum layer (b) directly laminated on the barrier layer (a) and having an average thickness of 30 nm or more and 100 nm or less. Specific modes and suitable modes of the barrier layer (a) and the vapor-deposited aluminum layer (b) are similar to the specific modes and the suitable modes of the barrier layer (A) and the vapor-deposited aluminum layer (B) of the vapor-deposited film of the present invention.

It is preferable that the vapor-deposited aluminum layer (b) includes an aluminum oxide layer (b1) and an aluminum layer (b2) sequentially arranged in this order from a face in contact with the barrier layer (a), that in an elemental analysis in a depth direction of the aluminum oxide layer (b1), a maximum value (O/Al)_{MAX} of a molar ratio of an oxygen element to an aluminum element, the molar ratio being measured using a scanning x-ray photoelectron spectrometer, is 0.5 or more and 2.0 or less, and that in a depth-direction analysis of the aluminum layer (b2), a minimum value (O/Al)_{MIN} of a molar ratio of an oxygen element to an aluminum element, the molar ratio being measured using a scanning x-ray photoelectron spectrometer, is less than 0.5. It is more preferable that the vapor-deposited aluminum layer (b) includes an aluminum oxide layer (b3) including a face(s) opposite to the face in contact with the barrier layer (a) and that in an elemental analysis of the face(s), a molar ratio (O/Al) s of an oxygen element to an aluminum element, the molar ratio being measured using a scanning x-ray photoelectron spectrometer, is 0.5 or more and 2.0 or less. Specific modes and suitable modes of the aluminum oxide layer (b1), the aluminum layer (b2), and the aluminum oxide layer (b3) are similar to the specific modes and the suitable modes of the aluminum oxide layer (B1), the aluminum layer (B2), and the aluminum oxide layer (B3) in the vapor-deposited aluminum layer (B) of the vapor-deposited film of the present invention.

The multilayer structure of the present invention may include two vapor-deposited films of the present invention. The multilayer structure of the present invention may include three or more vapor-deposited films of the present invention. In the case in which the multilayer structure of the present invention includes two or more vapor-deposited films of the present invention, these vapor-deposited films may be the same or different from each other.

### Polyamide Layer (F)

The multilayer structure of the present invention may further include the polyamide layer (F) laminated on the vapor-deposited film directly or with another layer interposed therebetween. When the multilayer structure includes the polyamide layer (F), the gas barrier properties and the like can be further improved.

The vapor-deposited film and the polyamide layer (F) may be directly laminated or may be laminated with an other layer interposed therebetween. Examples of the other layer include an adhesive layer, the polyolefin layer (E), and the like. A plurality of layers may be present between the plurality of vapor-deposited films.

The polyamide layer (F) is preferably at least one of the topmost layers of the multilayer structure. In the case in which the multilayer structure of the present invention is formed into a bag shape, the outermost layer may be the polyamide layer (F). In one embodiment of the multilayer structure of the present invention, one topmost layer may be the polyolefin layer (E), and the other topmost layer may be the polyamide layer (F).

The polyamide layer (F) typically contains polyamide as a principal component. The polyamide is a resin containing an amide bond. The polyamide can be obtained, for example, by ring-opening polymerization of lactam having a three or more membered ring, polycondensation of polymerizable ω-amino acids, polycondensation between a dibasic acid and a diamine, or the like. Examples of the polyamide include polycapramide (nylon 6), poly-ω-aminoheptanoic acid (nylon 7), poly-ω-aminononanoic acid (nylon 9), polyundecanamide (nylon 11), polylauryl lactam (nylon 12), polyethylene diamine adipamide (nylon 26), polytetramethylene adipamide (nylon 46), polyhexamethylene adipamide (nylon 66), polyhexamethylene sebacamide (nylon 610), polyhexamethylene dodecanamide (nylon 612), polyoctamethylene adipamide (nylon 86), polydecamethylene adipamide (nylon 108), a caprolactam/lauryl lactam copolymer (nylon 6/12), a caprolactam/ω-aminononanoic acid copolymer (nylon 6/9), a caprolactam/hexamethylene diammonium adipate copolymer (nylon 6/66), a lauryl lactam/hexamethylene diammonium adipate copolymer (nylon 12/66), a hexamethylene diammonium adipate/hexamethylene diammonium sebacate copolymer (nylon 66/610), an ethylene diammonium adipate/hexamethylene diammonium adipate copolymer (nylon 26/66), a caprolactam/hexamethylene diammonium adipate/hexamethylene diammonium sebacate copolymer (nylon 6/66/610), polyhexamethylene isophthalamide (nylon 6I), polyhexamethylene terephthalamide (nylon 6T), a hexamethylene isophthalamide/terephthalamide copolymer (nylon 61/6T), and the like.

A content of the polyamide in the polyamide layer (F) is preferably 80% by mass or more and 100% by mass or less, more preferably 90% by mass or more and 100% by mass or less, and more preferably 97% by mass or more and 100% by mass or less. The polyamide layer (F) may contain, as a component other than the polyamide, an antioxidant, an ultraviolet absorbing agent, a plasticizer, an antistatic agent, a lubricant, a coloring agent, a filler, a thermal stabilizer, a resin other than the polyamide, or the like.

The polyamide layer (F) may be an unoriented layer or an oriented layer.

The lower limit of an average thickness of the polyamide layer (F) is preferably 1 μm, more preferably 3 μm, still more preferably 5 μm, and even still more preferably 10 μm. When the average thickness of the polyamide layer (F) is greater than or equal to the lower limit, the gas barrier properties, the bending resistance, the storage stability, and the like can be improved. The upper limit of the average thickness of the polyamide layer (F) is preferably 100 μm, more preferably 50 μm, and may be 30 μm. When the average thickness of the polyamide layer (F) is less than or equal to the upper limit, for example, the thickness of the multilayer structure can be reduced.

The polyamide layer (F) may consist of a single layer or a plurality of layers.

### Other Layer(s)

The multilayer structure of the present invention may include other layer(s) besides the vapor-deposited film, the polyolefin layer (E), and the polyamide layer (F) described above. Examples of the other layer(s) include an adhesive layer, another thermoplastic resin layer, a paper layer, a metal foil layer, and the like.

In the case in which the multilayer structure of the present invention includes an adhesive layer, an average thickness of the adhesive layer is, for example, preferably 0.1 μm or more and 10 μm or less, more preferably 0.3 μm or more and 5 μm or less, and still more preferably 0.5 μm or more and 3 μm or less. When the average thickness of the adhesive layer falls within the above range, for example, the weight of the multilayer structure can be reduced, while sufficient adhesiveness is exerted.

### Layer Configuration, Etc.

Examples of a layer configuration of the multilayer structure of the present invention include:
(1) vapor-deposited film//E;
(2) vapor-deposited film//F/E;
(3) E//vapor-deposited film//E;
(4) E//vapor-deposited film//E//E;
(5) F//vapor-deposited film//E;
(6) E//vapor-deposited film//F//E;
(7) F//vapor-deposited film//F//E;
(8) E//vapor-deposited film//vapor-deposited film//E;
(9) F//vapor-deposited film//vapor-deposited film//E;
(10) vapor-deposited film//vapor-deposited film//vapor-deposited film//E; and
(11) F/vapor-deposited film//vapor-deposited film//vapor-deposited film//E.

It is to be noted that E denotes the polyolefin layer and F denotes the polyamide layer. Of the layer configurations listed above, the one in which another layer is disposed at an arbitrary position is also an example of the multilayer structure of the present invention. The layer configuration of the vapor-deposited film in each of the layer configurations listed above is as described above. Furthermore, the orientation of the vapor-deposited film is not particularly limited. For example, in the case the multilayer structure having the layer configuration (1) “vapor-deposited film//E” includes a vapor-deposited film having a layer configuration “A/B,” the layer configuration may be either “A/B//E” or “B/A//E.”

In the multilayer structure of the present invention, a thickness percentage of the barrier layer (A) with respect to a total thickness of the multilayer structure (average thickness of the barrier layer (A) with respect to an average thickness of the entire multilayer structure) may be, for example, 10% or less, is preferably 5% or less, and may be more preferably 4% or less, 3% or less, or 2% or less. When the thickness percentage of the barrier layer (A) is less than or equal to the upper limit, advantages such as an improvement in recyclability and the like can be obtained. For example, superior compatibility can be obtained at a time of retrieving and performing melt molding, and thus, a recycled product having good appearance can be formed. The lower limit of the thickness percentage of the barrier layer (A) is preferably 0.1% and may be more preferably 0.2%, 0.5%, or 1%. When the thickness percentage of the barrier layer (A) is greater than or equal to the lower limit, for example, the gas barrier properties can be improved.

The lower limit of an average thickness of the multilayer structure of the present invention (average thickness of the entire multilayer structure) is preferably 10 μm and may be 20 μm, 30 μm, or 50 μm. When the average thickness of the multilayer structure is greater than or equal to the lower limit, the gas barrier properties, the bending resistance, the storage stability, and the like can be further improved. The upper limit of the average thickness of the multilayer structure is preferably 1,000 μm and may be 500 μm, 300 μm, 200 μm, or 100 μm. When the average thickness of the multilayer structure is less than or equal to the upper limit, a weight reduction, an improvement in formability, and the like can be achieved.

The multilayer structure of the present invention can also be pulverized for the purpose of reuse to be used as a melt molding material. The multilayer structure can be used by being mixed with another melt molding material (another recycled resin, an unused resin, etc.). The multilayer structure may be entirely reused as a melt molding material, or only a part of the multilayer structure may be separated and reused as a melt molding material.

A method for producing the multilayer structure of the present invention is not particularly limited. For example, the multilayer structure can be obtained in such a manner that a film of the polyolefin layer (E), a film of the polyamide layer (F), another vapor-deposited film, and/or the like are/is laminated on the vapor-deposited film by a known means such as dry lamination or the like. Alternatively, the multilayer structure may be obtained in such a manner that the polyolefin layer (E), the polyamide layer (F), and/or the like are/is laminated on the vapor-deposited film, for example, by melt extrusion.

Examples of an application of the multilayer structure of the present invention include: a variety of packaging materials for food packaging, medical packaging, industrial chemical packaging, agrochemical packaging, etc.; a vacuum insulated bag; and the like.

### Packaging Material

A packaging material of the present invention includes the vapor-deposited film of the present invention or the multilayer structure of the present invention. The packaging material is used for packaging, and the shape thereof is not limited. The packaging material may be sheet-shaped or may be formed into a predetermined shape such as a bag shape or the like. In light of the heat sealing properties and the like, a topmost layer is preferably the polyolefin layer (D) or the polyolefin layer (E) serving as a thermal fusion layer. Furthermore, in light of the heat sealing properties and the like, the polyolefin layer (D) or the polyolefin layer (E) which is the topmost layer is preferably unoriented. In a case of a packaging material formed into a shape having the inside and the outside, such as a bag shape or the like, at least the innermost layer is preferably the polyolefin layer (D) or the polyolefin layer (E). In light of further inhibiting deterioration in gas barrier properties after storage of the packaging material, the vapor-deposited aluminum layer (B) is preferably disposed on the outer side than the barrier layer (A). Specific examples of a preferable layer configuration of the packaging material include {outer layer side (E)/(B)/(A)/(C)/(D)//(E) inner layer side} and the like. In particular, it is preferable that (A)/(C)/(D) are oriented and (E) is unoriented, because this configuration enables that both the mechanical strength and the heat sealing properties of the packaging material tend to be obtained. Furthermore, when the total thickness of the inner layers (D)//(E) is 55 μm or more, deterioration in gas barrier properties after storage can be inhibited even in a case in which specific contents (contents having a water activity of 0.9 or more, having a salt content of 0.5 g/g or more, or containing oil) are packaged.

The packaging material of the present invention is used, for example, for packaging foods, beverages, chemicals, medical equipment, machine parts, clothing items, and the like. Especially, the packaging material is preferably used for applications which require barrier properties against oxygen and applications in which the inside of the packaging material is replaced with a variety of functional gases. Since the packaging material includes the vapor-deposited film of the present invention, deterioration in gas barrier properties after bending treatment and after storage is inhibited, and thus, superior gas barrier properties can be maintained for a long period of time. Furthermore, in the packaging material of the present invention, the vapor-deposited aluminum layer (B) is less likely to be peeled from the barrier layer (A), and thus, deterioration in appearance after storage is also inhibited.

The packaging material is formed in a variety of modes in accordance with the application, for example, a vertical bag-making and filling seal bag, a pouch with spout, a laminated tube container, a container lid material, a vacuum packaging bag, and the like.

The vertical bag-making and filling seal bag is used, for example, for packaging foods, beverages, and the like in the form of a liquid, a viscous body, a powder, loose solids, or a combination thereof. The vertical bag-making and filling seal bag is formed by heat-sealing the vapor-deposited film or the multilayer structure. In the case of performing heat sealing, it is typically necessary to provide, in the vapor-deposited film or the multilayer structure, a heat-sealable layer (for example, the polyolefin layer (D) or the polyolefin layer (E)) either as an inner layer of the vertical bag-making and filling seal bag or as both the inner layer and an outer layer of the vertical bag-making and filling seal bag. In the case in which the heat-sealable layer is only on the inner side of the vertical bag-making and filling seal bag, a body portion is typically sealed by pillow sealing. In the case in which the heat-sealable layer is on both the inner side and the outer side of the vertical bag-making and filling seal bag, the body portion is typically sealed by envelope sealing.

The pouch with spout is used for packaging liquid substances, for example, liquid beverages such as soft drinks, jerries, yogurt, fruit sauces, seasonings, functional water, liquid diets, and the like. The laminated tube container is used, for example, for packaging cosmetics, chemicals, medicines, foods, tooth pastes, and the like. The container lid material is a lid material for a container in which foods such as processed meat, processed vegetables, processed seafoods or fruits is packed.

### Vacuum Packaging Bag

A vacuum packaging bag of the present invention includes a packaging bag formed from the packaging material of the present invention, and an inside of the packaging bag has a reduced pressure. Examples of an application of the vacuum bag include applications in which packaging in a vacuum state is desired, for example, storage of foods, beverages, etc., a sheathing material for a vacuum insulator, and the like. Since such a vacuum packaging bag includes the vapor-deposited film of the present invention, deterioration in gas barrier properties after bending treatment and after storage is inhibited, and thus, a high vacuum state can be maintained for a long period of time. A multilayer structure which is suitably used in the vacuum packaging bag preferably includes a plurality of vapor-deposited films. Furthermore, in a case in which high mechanical strength is required, the polyamide layer (F) is preferably provided. Examples of a layer configuration of the multilayer structure which is suitably used in the vacuum packaging bag include {outside (F)/(A)/(B)//(A)/(B)//(E) inside}, {outside (F)/(A)/(B)/(B)/(A)/(E) inside}, and the like, wherein it is more preferable that one of the barrier layers (A) is an EVOH and the other is PET.

### Vacuum Insulator

A vacuum insulator of the present invention includes: the vacuum packaging bag of the present invention; and a core material disposed inside the vacuum packaging bag. In the vacuum insulator, the vacuum packaging bag is also referred to as an outer packaging material. The vacuum insulator is used for applications which require keeping cool, warm, etc. Examples of the core material include fiberglass, polyurethane foam, and the like. In the vacuum insulator, the core material is vacuum-encapsulated in the vacuum packaging bag (outer packaging material). The vacuum packaging bag (outer packaging material) is formed, for example, by heat-sealing the vapor-deposited film or the multilayer structure.

In the vacuum insulator of the present invention, the vacuum packaging bag (outer packaging material) includes the vapor-deposited film; therefore, deterioration in gas barrier properties after bending treatment and after storage is inhibited, and thus, a high insulating effect can be maintained for a long period of time. The vacuum insulator can be utilized as: heat insulators for household electronics such as refrigerators, hot-water supply equipment, rice cookers, etc.; residential heat insulators used in wall portions, ceiling portions, attic portions, floor portions, etc.; car roof materials; heat insulating panels of vending machines etc.; and the like.

### EXAMPLES

Hereinafter, the present invention is described in detail by way of Examples, and the present invention is not limited to these Examples.

It is to be noted that hereinafter, a vapor-deposited aluminum layer may be abbreviated as “vapor-deposited Al layer,” a polyolefin may be abbreviated as “PO,” and a polyamide may be abbreviated as “PA.”

### Materials 1 Used

### Barrier Layer (A)

EVOH-1: an EVOH having an ethylene unit content of 32 mol %, a degree of saponification of 99.9 mol %, and a MFR (190 °C, load of 2.16 kg) of 1.6 g/10 min
OPET: “Lumirror (registered trademark) P60” (produced by Toray Industries, Inc., biaxially oriented PET film; average thickness: 12 μm)

### Evaluation Method 1

### (1) Molar Ratio (O/Al) of Oxygen Element to Aluminum Element in Vapor-Deposited Aluminum Layer (B)

With regard to the vapor-deposited aluminum layer (B) of each of vapor-deposited films obtained in Examples and Comparative Examples, a molar ratio (O/Al) of an oxygen element to an aluminum element was measured using a scanning x-ray photoelectron spectrometer “PHIQuntera SXM”, produced by ULVAC-PHI, Inc., while performing sputtering in argon in the thickness (depth) direction. It is to be noted that the measurement was performed under conditions in which AlKα (1486.6 eV) was used as an X-ray source, the X-ray beam diameter was 100 μmφ (25 W, 15 kV), the measurement range was 300 μm wide×300 μm long, the signal acceptance angle was 45°, and the pressure was 1×10⁻⁶ Pa.

A molar ratio of an oxygen element to an aluminum element at a measurement point at which the molar ratio of an oxygen element observed on the barrier layer (A) side (i.e., observed in the aluminum oxide layer (B1)) was the maximum value was defined as (O/Al) MAX, and a molar ratio of an oxygen element to an aluminum element at a measurement point at which the molar ratio of an oxygen element was the minimum value (i.e., in the aluminum layer (B2)) was defined as (O/Al) MIN. Furthermore, the molar ratio (O/Al) s of an oxygen element to an aluminum element in the face(S) of the vapor-deposited aluminum layer (B), the face(S) being opposite to the face in contact with the barrier layer (A) was also measured.

### (2) Oxygen Transmission Rate (OTR)

A part was cut out from each of the vapor-deposited films obtained in Examples and Comparative Examples, and the OTR thereof was measured according to the method disclosed in ISO14663-2 Annex C (1999) under conditions involving 20 °C and 65% RH by using an oxygen transmission rate measurement apparatus OX-TRAN 2/21, produced by MOCON INC. (detection limit: 0.01 mL/(m²·day·atm)) and was evaluated according to the following criteria.

### Determination Criteria

A: Less than 0.01 mL/(m²·day·atm) (under the detection limit)
B: 0.01 mL/(m²·day·atm) or more and less than 0.05 mL/(m²·day·atm)
C: 0.05 mL/(m²·day·atm) or more and less than 0.10 mL/(m²·day·atm)
D: 0.10 mL/(m²·day·atm) or more and less than 1.0 mL/(m²·day·atm)
E: 1.0 mL/(m²·day·atm) or more

### (3) OTR Difference Between Before and After Bending Test

A 21 cm×30 cm-sized sample was cut out from each of the vapor-deposited films obtained in Examples and Comparative Examples and was subjected to a Gelbo flex test (bending test) according to ASTM F 392 by using a Gelbo Flex Tester (BE-1005), produced by Tester Sangyo Co., Ltd. Specifically, in an atmosphere of 23 °C/50% RH, the vapor-deposited film which had been cut out was deformed into a cylindrical shape having a diameter of 3.5 inches, both ends thereof were fixed to the Gelbo Flex Tester, the initial interval and the interval at the maximum bending were set to 7 inches and 1 inch, respectively, the sample was twisted in an angle of 440° at first 3.5 inches of a stroke and then straightly and horizontally moved by the remaining 2.5 inches, and this repetitive reciprocal movement was performed three times. After the bending test, a part of the bent portion of the vapor-deposited film after the bending test was cut out, and the OTR thereof was measured according to the method disclosed in ISO14663-2 Annex C (1999) under conditions involving 20 °C and 65% RH by using an oxygen transmission rate measurement apparatus OX-TRAN 2/21, produced by MOCON INC. (detection limit: 0.01 mL/(m²·day·atm)). The OTR difference between before and after the bending test (OTR after the test-OTR before the test) was calculated, and this OTR difference was evaluated according to the following criteria. When the rating was A to D, the bending resistance was determined to be favorable.

### Determination Criteria

A: Less than 0.05 mL/(m²·day·atm)
B: 0.05 mL/(m²·day·atm) or more and less than 0.10 mL/(m²·day·atm)
C: 0.10 mL/(m²·day·atm) or more and less than 0.15 mL/(m²·day·atm)
D: 0.15 mL/(m²·day·atm) or more and less than 0.20 mL/(m²·day·atm)
E: 0.20 mL/(m²·day·atm) or more

### (4) OTR Difference Between Before and After Storage Test

By using a sample obtained by cutting out a part from each of the vapor-deposited films obtained in Examples and Comparative Examples, a storage test was performed in an atmosphere of 20 °C/65% RH for 20 days, and the oxygen transmission rate of the sample after the storage test was measured according to the method disclosed in ISO14663-2 Annex C (1999) under conditions involving 20 °C and 65% RH by using an oxygen transmission rate measurement apparatus OX-TRAN 2/21, produced by MOCON INC. (detection limit: 0.01 mL/(m²·day·atm)). The OTR difference between before and after the storage test (OTR after the test-OTR before the test) was calculated and evaluated according to the following criteria. When the rating was A to D, the storage stability was determined to be favorable.

### Determination Criteria

A: Less than 0.05 mL/(m²·day·atm)
B: 0.05 mL/(m²·day·atm) or more and less than 0.10 mL/(m²·day·atm)
C: 0.10 mL/(m²·day·atm) or more and less than 0.15 mL/(m²·day·atm)
D: 0.15 mL/(m²·day·atm) or more and less than 0.20 mL/(m²·day·atm)
E: 0.20 mL/(m²·day·atm) or more

### Example 1

An unoriented film having an average thickness of 170 μm was obtained in such a manner that by using a single-screw extruder, the EVOH-1 was melted at 240 °C and extruded from a die onto a casting roll, while the air was blown at a wind velocity of 30 m/sec by using an air knife. The obtained unoriented film was brought into contact with warm water at 80 °C for 10 sec, oriented by 3.2 times in the longitudinal direction and by 3.0 times in the lateral direction at 90 °C by using tenter-type simultaneous biaxial orientation equipment, and further subjected to heat treatment in a tenter set at 170 °C for 5 sec; in this manner, a biaxially oriented EVOH film (barrier layer (A)) having an average thickness of 12 μm and a total width of 3.6 m was obtained. While rolling up the obtained biaxially oriented EVOH film, a slit of a width of 80 cm was cut with respect to the central position of the film total width, whereby a 4,000-m-long biaxially oriented EVOH film was obtained.

By using a roll-type vacuum deposition apparatus “EWA-105”, produced by Japan Vacuum Engineering Co., Ltd., having a transport chamber and a vapor deposition chamber, the aluminum layer (B) was formed on the obtained biaxially oriented EVOH film (vapor deposition base) by the following procedure. The “EWA-105” was equipped with an unwinder and a winder on the transport chamber side, a crucible for heating aluminum and a cooling can for cooling the film while transporting it were provided in the vapor deposition chamber, and the film is transported along the cooling can. The obtained biaxially oriented EVOH film was transported at a transport velocity of 150 m/min by the cooling can cooled to −30 °C. In addition, a nozzle for directly blowing oxygen onto the biaxially oriented EVOH film before the vapor deposition (nozzle gap: 2 mm; nozzle width: 21 cm; film-nozzle distance: 2 cm; angle with respect to the film:) 30° was installed in the vapor deposition chamber, and aluminum was vacuum-deposited while blowing the oxygen at 80 mL/min; in this manner, a vapor-deposited film in which the vapor-deposited aluminum layer (B) having an average thickness of 40 nm was formed on the biaxially oriented EVOH film was produced. It is to be noted that the pressure in the vapor deposition chamber was 5×10⁻⁴ Pa to 9×10⁻⁴ Pa. The average thickness of the vapor-deposited aluminum layer (B) was adjusted by appropriately controlling the voltage applied to the crucible.

The obtained vapor-deposited film was subjected to each evaluation according to the methods described above in Sections (1) to (4) of Evaluation Method 1. The results are shown in Table 1.

### Examples 2 to 7 and Comparative Examples 1 to 3

Vapor-deposited films were produced and evaluated by the same procedure as in Example 1, except that the supply amount of oxygen blown during the vapor deposition was changed as in Table 1. The results are shown in Table 1.

### Example 8

A vapor-deposited film was produced and evaluated by the same procedure as in Example 1, except that the transport velocity of the biaxially oriented EVOH film during the vapor deposition was changed to 75 m/min and the vapor deposition was performed such that the average thickness of the vapor-deposited aluminum layer was 80 nm. The results are shown in Table 1.

### Example 9

An unoriented film was obtained by the same procedure as in Example 1, except that the average thickness was 12 μm. A vapor-deposited film was produced and evaluated by the same procedure as in Example 1, except that the obtained unoriented film was directly used as a vapor deposition base. The results are shown in Table 1.

A vapor-deposited film was produced and evaluated by the same procedure as in Example 1, except that the OPET was used instead of the biaxially oriented EVOH film. The results are shown in Table 1.

### Example 10

### Comparative Example 4

A vapor-deposited film was produced and evaluated by the same procedure as in Comparative Example 3, except that the OPET was used instead of the biaxially oriented EVOH film. The results are shown in Table 1.

### Comparative Example 5

A vapor-deposited film was produced and evaluated by the same procedure as in Comparative Example 3, except that a nozzle for directly blowing oxygen onto the vapor-deposited layer of the biaxially oriented EVOH film after the vapor deposition was installed in the vapor deposition chamber (nozzle gap: 2 mm; nozzle width: 21 cm; film-nozzle distance: 2 cm; angle with respect to the film:) 90°, that an oxygen gas was introduced under conditions involving 5,000 mL/min or more from the nozzle for directly blowing oxygen onto the vapor-deposited layer, and that the oxygen gas was introduced such that the pressure in the vapor deposition chamber was 1.0×10⁻² Pa to 5.0×10⁻² Pa. The results are shown in Table 1.

### Comparative Example 6

A vapor-deposited film was produced and evaluated by the same procedure as in Example 1, except that the supply amount of oxygen blown during the vapor deposition was 5,000 mL/min or more and an oxygen gas was introduced such that the pressure in the vapor deposition chamber was 1.0×10⁻² Pa to 5.0×10⁻² Pa. The results are shown in Table 1.

### Comparative Example 7

A vapor-deposited film was produced and evaluated by the same procedure as in Comparative Example 3, except that a nozzle for blowing oxygen was installed (nozzle gap: 2 mm; nozzle width: 21 cm) such that the oxygen could be blown into a gap between the crucible for heating aluminum in the vapor deposition chamber and the biaxially oriented EVOH film during transportation, and that aluminum oxide was vacuum-deposited while blowing the oxygen at 3,000 to 5,000 mL/min. The results are shown in Table 1.

TABLE 1

| | | | | | | Evaluation | | | | | |
|---|---|---|---|---|---|---|---|---|---|---|---|
| | | | | | | | | | OTR | | |
| | Vapor-deposited film | | | | | | | | | difference | difference |
| | | | | vapor-deposited | | molar ratio (O/Al) of vapor- | | | | between | between |
| | barrier layer (A) | | | Al layer (B) | | deposited Al layer (B) | | | | before | before |
| | | average | orient- | average | oxygen | B1 | B2 | B3 | before | and after | and after |
| | type | thickness | ation | thickness | supply rate | (O/A1)_{MAX} | (O/A1)_{MIN} | (O/A1)_{S} | test | bending test | storage test |
| Unit | — | μm | — | nm | mL/min | — | — | — | — | — | — |
| Example 1 | EVOH-1 | 12 | biaxially | 40 | 80 | 1.36 | 0.02 | 1.58 | A | B | B |
| | | | oriented | | | | | | | | |
| Example 2 | EVOH-1 | 12 | biaxially | 40 | 100 | 1.48 | 0.02 | 1.53 | A | B | B |
| | | | oriented | | | | | | | | |
| Example 3 | EVOH-1 | 12 | biaxially | 40 | 130 | 1.77 | 0.03 | 1.72 | A | C | B |
| | | | oriented | | | | | | | | |
| Example 4 | EVOH-1 | 12 | biaxially | 40 | 160 | 1.93 | 0.03 | 1.82 | B | D | C |
| | | | oriented | | | | | | | | |
| Example 5 | EVOH-1 | 12 | biaxially | 40 | 70 | 1.12 | 0.02 | 1.67 | A | B | B |
| | | | oriented | | | | | | | | |
| Example 6 | EVOH-1 | 12 | biaxially | 40 | 50 | 0.87 | 0.03 | 1.48 | B | B | C |
| | | | oriented | | | | | | | | |
| Example 7 | EVOH-1 | 12 | biaxially | 40 | 30 | 0.53 | 0.04 | 1.41 | B | B | D |
| | | | oriented | | | | | | | | |
| Example 8 | EVOH-1 | 12 | biaxially | 80 | 80 | 1.25 | 0.03 | 1.33 | A | A | A |
| | | | oriented | | | | | | | | |
| Example 9 | EVOH-1 | 12 | un- | 40 | 80 | 1.31 | 0.04 | 1.52 | B | C | D |
| | | | oriented | | | | | | | | |
| Example 10 | OPET | 12 | biaxially | 40 | 80 | 1.36 | 0.02 | 1.64 | D | D | C |
| | | | oriented | | | | | | | | |
| Comparative | EVOH-1 | 12 | biaxially | 40 | 200 | 2.32 | 0.03 | 1.24 | C | E | C |
| Example 1 | | | oriented | | | | | | | | |
| Comparative | EVOH-1 | 12 | biaxially | 40 | 10 | 0.27 | 0.03 | 1.32 | B | B | E |
| Example 2 | | | oriented | | | | | | | | |
| Comparative | EVOH-1 | 12 | biaxially | 40 | 0 | 0.13 | 0.01 | 1.32 | B | B | E |
| Example 3 | | | oriented | | | | | | | | |
| Comparative | OPET | 12 | biaxially | 40 | 0 | 0.08 | 0.03 | 1.59 | D | E | E |
| Example 4 | | | oriented | | | | | | | | |
| Comparative | EVOH-1 | 12 | biaxially | 40 | >5,000^{*1} | 0.09 | 0.06 | 3.12 | C | E | D |
| Example 5 | | | oriented | | | | | | | | |
| Comparative | EVOH-1 | 12 | biaxially | 40 | >5,000 | 3.42 | 0.06 | 1.31 | C | E | D |
| Example 6 | | | oriented | | | | | | | | |
| Comparative | EVOH-1 | 12 | biaxially | 40 | 3,000 to | 1.73 | 1.72 | 1.68 | C | C | E |
| Example 7 | | | oriented | | 5,000 | | | | | | |

^{*1}The oxygen gas was blown onto the vapor-deposited layer after the vapor deposition.

### Materials 2 Used

### Barrier Layer (A) and Barrier Layer (a)

EVOH-1: an EVOH having an ethylene unit content of 32 mol %, a degree of saponification of 99.9 mol %, and a MFR (190 °C, under the load of 2.16 kg) of 1.6 g/10 min
OPET: “Lumirror (registered trademark) P60” (produced by Toray Industries, Inc., biaxially oriented PET film; average thickness: 12 μm)

### PO Layer (E)

LLDPE: “Unilux (registered trademark) LS760C” (produced by Idemitsu Unitech Co., Ltd., LLDPE film; average thickness: 50 μm)

### PA Layer (F)

OPA: “EMBLEM (registered trademark) ONM15,” biaxially oriented polyamide film; average thickness: 15 μm

### Evaluation Method 2

### (5) Thermal Conductivity

After each of vacuum insulators obtained in Examples and Comparative Examples was stored at 23 °C and 50% RH for 1 week, the thermal conductivity (mW/(m·k)) of the vacuum insulator was measured using a thermal conductivity measurement apparatus (FOX314, produced by EKO Instruments Co., Ltd.), wherein the temperature on one side of the vacuum insulator was set to 38 °C and the temperature on the other face side was set to 12 °C. The evaluation was conducted twice, an average value of the two evaluation results was defined as a thermal conductivity before the test, and the results were evaluated according to the following criteria. When the evaluation results were A or B, the heat insulation performance was determined to be favorable.

### Thermal Conductivity Before Test (Determination Criteria)

A: 2.5 mW/m·K or less
B: Greater than 2.5 mW/m·K and 2.8 mW/m·K or less
C: Greater than 2.8 mW/m·K

Each of the vacuum insulators obtained in Examples and Comparative Examples was bent along a semicircular arc of R=115 mm. After storage at 23 °C and 50% RH for 1 week, the bent vacuum insulator was pressed against a horizontal plate to restore the flat plate shape, and then, the thermal conductivity of the vacuum insulator was measured in the same manner as above. The evaluation was conducted twice, an average value of the two evaluation results was defined as a thermal conductivity after the bending test, the difference in thermal conductivity between before and after the bending test (after the bending test-before the bending test) was calculated, and the results were evaluated according to the following criteria. When the evaluation results were A to C, the bending resistance was determined to be favorable. That is to say, it is considered that deterioration in gas barrier properties after bending treatment is inhibited, and accordingly, a decrease in thermal conductivity due to bending is inhibited.

### Difference in Thermal Conductivity Between Before and After Bending Test

### (Determination Criteria)

A: 0.1 mW/m·K or less
B: Greater than 0.1 mW/m·K and 0.3 mW/m·K or less
C: Greater than 0.3 mW/m·K and 0.5 mW/m·K or less
D: Greater than 0.5 mW/m·K

Each of the vacuum insulators obtained in Examples and Comparative Examples was bent along a semicircular arc of R=115 mm. After storage at 23 °C and 50% RH for 1 week, the bent vacuum insulator was stored in a dryer at 80 °C for 60 days, pressed against a horizontal plate to restore the flat plate shape, and then stored at 23 °C and 50% RH for 1 week, and the thermal conductivity was measured using a thermal conductivity measurement apparatus in the same manner as above. The evaluation was conducted twice, an average value of the two evaluation results was defined as a thermal conductivity after the storage test, the difference between before and after the storage test (after the storage test-after the bending test) was calculated, and the results were evaluated according to the following criteria. When the evaluation results were A to C, the storage stability was determined to be favorable. That is to say, it is considered that deterioration in gas barrier properties after storage is inhibited, and accordingly, a decrease in thermal conductivity after storage is inhibited.

Difference in Thermal Conductivity Between Before and After Storage Test (Determination Criteria)
A: 7.0 mW/m·K or less
B: Greater than 7.0 mW/m·K and 11.0 mW/m·K or less
C: Greater than 11.0 mW/m·K and 15.0 mW/m·K or less
D: Greater than 15.0 mW/m·K and 15.0 mW/m·K or less

### Example 11

The vapor-deposited film obtained in Example 8 was prepared as a first vapor-deposited film.

A second vapor-deposited film (OPET/Al=12 μm/50 nm) was produced by the same operation as in Example 10, except that the transport velocity of the PET during the vapor deposition was changed to 94 m/min and the vapor deposition was performed such that the average thickness of the vapor-deposited aluminum layer was 50 nm. With regard to the obtained second vapor-deposited film, the molar ratio (O/Al) of an oxygen element to an aluminum element in the vapor-deposited aluminum layer was measured according to the method described above in Section (1) of Evaluation Method 1. The results are shown in Table 3. Furthermore, the results of the molar ratio measurement of the vapor-deposited film obtained in Example 8 (first vapor-deposited film) are also shown in Table 3 again. It is to be noted that the vapor-deposited aluminum layer of the vapor-deposited film of Example 8 (first vapor-deposited film) is referred to as the vapor-deposited aluminum layer (B), and the vapor-deposited aluminum layer of the second vapor-deposited film is referred to as the vapor-deposited aluminum layer (b).

A surface of the vapor-deposited aluminum layer of the second vapor-deposited film, one face of the OPA, and one face of the LLDPE were each coated with a two-component urethane adhesive (“TAKELAC (trademark) A-520” and “TAKENATE (trademark) A-50,” produced by Mitsui Chemicals, Inc.) such that the average thickness of the adhesive after drying was 1.0 μm, and drying was performed. A multilayer structure was produced in such a manner that by using also the first vapor-deposited film, lamination was performed to obtain a configuration of OPA/tie/PET/Al/tie/Al/EVOH-1/tie/LLDPE (tie means the adhesive layer, and Al means the vapor-deposited aluminum layer).

A vacuum insulator was produced using the obtained multilayer structure. Specifically, the multilayer structure was cut into a size of 20 cm×40 cm to produce two cover materials, the two cover materials were superimposed such that the LLDPE layers were the inner faces, and three sides were heat-sealed to a width of 10 mm to produce a three-sided bag as a packaging bag. Through an opening of the obtained packaging bag, fiberglass dried in an atmosphere at 160 °C for 4 hrs and a packet of calcium oxide were charged as a low-thermal-conductivity core material and as an adsorbent, respectively, and the packaging bag in a state of having an internal pressure of 1.0 Pa was sealed at a temperature of 20 °C by using a vacuum insulation panel production apparatus (KT-500RD, produced by NPC Incorporated) to produce the vacuum insulator. The thermal conductivity of the obtained vacuum insulator was evaluated according to the method described above in Section (5) of Evaluation Method 2. The results are shown in Table 3.

### Examples 12 and 13

Vapor-deposited films, multilayer structures, and vacuum insulators were produced and evaluated by the same procedure as in Example 11, except that the vapor-deposited films were each produced by the same procedure as in Example 8, except that the supply amount of oxygen blown during the vapor deposition was changed as in Table 2, and used as the first vapor-deposited film. The results are shown in Table 3.

### Example 14

An unoriented film was obtained by the same procedure as in Example 8, except that the average thickness was 12 μm. A vapor-deposited film, a multilayer structure, and a vacuum insulator were produced and evaluated by the same procedure as in Example 11, except that the vapor-deposited film was produced by the same procedure as in Example 8, except that the obtained unoriented film was directly used as a vapor deposition base, and used as the first vapor-deposited film. The results are shown in Table 3.

### Example 15

A vapor-deposited film, a multilayer structure, and a vacuum insulator were produced and evaluated by the same procedure as in Example 11, except that the vapor-deposited film obtained in Example 1 was used as the first vapor-deposited film. The results are shown in Table 3.

### Comparative Example 8

A vapor-deposited film, a multilayer structure, and a vacuum insulator were produced and evaluated by the same procedure as in Example 11, except that the vapor-deposited film obtained in Comparative Example 1 was used as the first vapor-deposited film and that oxygen was not blown during the formation of the second vapor-deposited film. The results are shown in Table 3.

### Comparative Example 9

A vapor-deposited film, a multilayer structure, and a vacuum insulator were produced and evaluated by the same procedure as in Comparative Example 8, except that the vapor-deposited film obtained in Comparative Example 2 was used as the first vapor-deposited film. The results are shown in Table 3.

### Comparative Example 10

A vapor-deposited film, a multilayer structure, and a vacuum insulator were produced and evaluated by the same procedure as in Comparative Example 8, except that the vapor-deposited film obtained in Comparative Example 3 was used as the first vapor-deposited film. The results are shown in Table 3.

TABLE 2

| | Multilayer structure | | | | | | | | | | | | |
|---|---|---|---|---|---|---|---|---|---|---|---|---|---|
| | first vapor-deposited film | | | | | second vapor-deposited film | | | | | | | |
| | | | | vapor-deposited | | | | vapor-deposited | | | | | |
| | barrier layer (A) | | | A1 layer (B) | | barrier layer (a) | | A1 layer (b) | | PO layer (E) | | PA layer (F) | |
| | | average | | average | oxygen | | average | average | oxygen | | average | | average |
| | | thick- | orient- | thick- | supply | | thick- | thick- | supply | | thick- | | thick- |
| | type | ness | ation | ness | rate | type | ness | ness | rate | type | ness | type | ness |
| Unit | — | μm | — | nm | mL/min | — | μm | nm | mL/min | — | μm | — | μm |
| Example 11 | EVOH-1 | 12 | biaxially | 80 | 80 | OPET | 12 | 50 | 80 | LLDPE | 50 | OPA | 15 |
| | | | oriented | | | | | | | | | | |
| Example 12 | EVOH-1 | 12 | biaxially | 80 | 160 | OPET | 12 | 50 | 80 | LLDPE | 50 | OPA | 15 |
| | | | oriented | | | | | | | | | | |
| Example 13 | EVOH-1 | 12 | biaxially | 80 | 30 | OPET | 12 | 50 | 80 | LLDPE | 50 | OPA | 15 |
| | | | oriented | | | | | | | | | | |
| Example 14 | EVOH-1 | 12 | un- | 80 | 80 | OPET | 12 | 50 | 80 | LLDPE | 50 | OPA | 15 |
| | | | oriented | | | | | | | | | | |
| Example 15 | EVOH-1 | 12 | biaxially | 40 | 80 | OPET | 12 | 50 | 80 | LLDPE | 50 | OPA | 15 |
| | | | oriented | | | | | | | | | | |
| Com- | EVOH-1 | 12 | biaxially | 40 | 200 | OPET | 12 | 50 | 0 | LLDPE | 50 | OPA | 15 |
| parative | | | | | | | | | | | | | |
| Example 8 | | | oriented | | | | | | | | | | |
| Com- | EVOH-1 | 12 | biaxially | 40 | 10 | OPET | 12 | 50 | 0 | LLDPE | 50 | OPA | 15 |
| parative | | | | | | | | | | | | | |
| Example 9 | | | oriented | | | | | | | | | | |
| Com- | EVOH-1 | 12 | biaxially | 40 | 0 | OPET | 12 | 50 | 0 | LLDPE | 50 | OPA | 15 |
| parative | | | | | | | | | | | | | |
| Example 10 | | | oriented | | | | | | | | | | |

TABLE 3

| | Evaluation | | | | | | | | |
|---|---|---|---|---|---|---|---|---|---|
| | | | | | | | thermal conductivity | | |
| | molar ratio (O/A1) of vapor- | | | molar ratio (O/A1) of vapor- | | | | difference | difference |
| | deposited A1 layer (B) | | | deposited A1 layer (b) | | | | between | between |
| | B1 | B2 | B3 | b1 | b2 | b3 | before | before and after | before and after |
| | (O/A1)_{MAX} | (O/A1)_{MIN} | (O/A1)_{S} | (O/A1)_{MAX} | (O/A1)_{MIN} | (O/A1)_{S} | test | bending test | storage test |
| Unit | — | — | — | — | — | — | — | — | — |
| Example 11 | 1.25 | 0.03 | 1.33 | 1.25 | 0.03 | 1.31 | A | A | A |
| Example 12 | 1.95 | 0.04 | 1.62 | 1.25 | 0.03 | 1.31 | A | B | B |
| Example 13 | 0.58 | 0.01 | 1.22 | 1.25 | 0.03 | 1.31 | A | B | B |
| Example 14 | 1.33 | 0.03 | 1.42 | 1.25 | 0.03 | 1.31 | B | C | C |
| Example 15 | 1.36 | 0.02 | 1.58 | 1.25 | 0.03 | 1.31 | A | C | C |
| Comparative | 2.32 | 0.03 | 1.24 | 0.15 | 0.01 | 1.24 | C | D | D |
| Example 8 | | | | | | | | | |
| Comparative | 0.27 | 0.03 | 1.32 | 0.15 | 0.01 | 1.24 | B | B | D |
| Example 9 | | | | | | | | | |
| Comparative | 0.13 | 0.01 | 1.32 | 0.15 | 0.01 | 1.24 | B | B | D |
| Example 10 | | | | | | | | | |

### Materials 3 Used

### Barrier Layer (A)

EVOH-2: an EVOH having an ethylene unit content of 48 mol %, a degree of saponification of 99.9 mol %, and a MFR (190 °C, load of 2.16 kg) of 6.4 g/10 min
EVOH-3: an EVOH having an ethylene unit content of 32 mol %, a degree of saponification of 99.9 mol %, and a MFR (190 °C, load of 2.16 kg) of 1.6 g/10 min
OPET: “Lumirror (registered trademark) P60” (produced by Toray Industries, Inc., biaxially oriented PET film; average thickness: 12 μm)

### Adhesive Resin Layer (C)

Ad: “ADMER (registered trademark) NF528” (produced by Mitsui Chemicals, Inc., maleic anhydride-modified polyethylene)

### PO Layer (D)

PP: “Novatec (registered trademark) FL203D” (produced by Japan Polypropylene Corporation, polypropylene)

### PO Layer (E)

OPP: “FOR” (produced by Futamura Chemical Co., Ltd., biaxially oriented polypropylene film; average thickness: 20 μm)
CPP30: “GLC” (Mitsui Chemicals Tohcello Inc., unoriented polypropylene film; average thickness: 30 μm)
CPP50: “GLC” (Mitsui Chemicals Tohcello Inc., unoriented polypropylene film; average thickness: 50 μm)

### Evaluation Method 3

### (6) OTR Before Storage Test

A measurement sample having a size of 11 cm×11 cm was cut out from each of the multilayer structures obtained in Examples and Comparative Examples, the measurement sample which had been cut out was left to stand still at 20 °C and 65% RH for 1 week, and then, the oxygen transmission rate thereof was measured according to the method disclosed in ISO14663-2 Annex C (1999) under conditions involving 20 °C and 65% RH by using an oxygen transmission rate measurement apparatus OX-TRAN 2/21, produced by MOCON INC. (detection limit: 0.01 mL/(m²·day·atm)), and the results were evaluated according to the following criteria.

### Determination Criteria

A: Less than 0.01 mL/(m²·day·atm)
B: 0.01 mL/(m²·day·atm) or more and less than 0.05 mL/(m²·day·atm)
C: 0.05 mL/(m²·day·atm) or more and less than 0.10 mL/(m²·day·atm)
D: 0.10 mL/(m²·day·atm) or more and less than 0.2 mL/(m²·day·atm)
E: 0.2 mL/(m²·day·atm) or more
   (7) OTR and Appearance after Storage Test

The following storage test was performed: each of ketchup pouches obtained in Examples and Comparative Examples was stored for 150 days in a thermo-hygrostat set at 43 °C and 50% RH. After the storage test, an upper portion of the pouch was cut, the ketchup was squeezed, an adhering substance was washed off with pure water, the remaining pure water was wiped away with a tissue, and then, a square of 11 cm×11 cm was cut out from a central portion of the pouch (not including the sealed portion), the measurement sample which had been cut out was conditioned at 20 °C and 65% RH for 1 week, the oxygen transmission rate thereof was measured according to the method disclosed in ISO14663-2 Annex C (1999) under conditions involving 20 °C and 65% RH by using an oxygen transmission rate measurement apparatus OX-TRAN 2/21, produced by MOCON INC. (detection limit: 0.01 mL/(m²·day·atm)), and the results were evaluated according to the following criteria.

### Determination Criteria of OTR

A: Less than 0.1 mL/(m²·day·atm)
B: 0.1 mL/(m²·day·atm) or more and less than 0.5 mL/(m²·day·atm)
C: 0.5 mL/(m²·day·atm) or more and less than 1.0 mL/(m²·day·atm)
D: 1.0 mL/(m²·day·atm) or more and less than 2.0 mL/(m²·day·atm)
E: 2.0 mL/(m²·day·atm) or more

Furthermore, the appearance after the storage test was evaluated according to the following criteria.

### Determination Criteria of Appearance

A: Comparable to the appearance before the storage test
B: A bleached part having a maximum length of 0.1 mm or more and less than 5 mm was observed.
C: A bleached part having a maximum length of 5 mm or more and less than 10 mm was observed.
D: A bleached part having a maximum length of 10 mm or more and less than 20 mm was observed.
E: A bleached part having a maximum length of 20 mm or more was observed.

### Example 16

The EVOH-2 was used as a material of the barrier layer (A), the Ad was used as a material of the adhesive resin layer (C), the PP was used as a material of the PO layer (D), and these materials were extruded from a die onto a casting roll by a three-type three-layer coextrusion cast molding method, while the air was blown at a wind velocity of 30 m/sec by using an air knife, to produce an unoriented multilayer film (EVOH-2/Ad/PP=10 μm/10 μm/180 μm) under the following conditions.

### Conditions for Forming Multilayer Film

### Apparatus: Three-Type Three-Layer Cast Film Coextruder

Barrier Layer (A): EVOH-2
Extruder: single-screw extruder (laboratory extruder ME-type CO-EXT, Toyo Seiki Co., Ltd.)
Screw: diameter=20 mmφ, L/D=20, full flight screw
Extrusion temperature: feeding zone/compression zone/metering zone/die=175/200/220/220 °C.

### Adhesive Resin Layer (C): Ad

Extruder: single-screw extruder (SZW20GT-20 MG, Technovel Corporation)
Screw: diameter=20 mmφ, L/D=20, full flight screw
Extrusion temperature: feeding zone/compression zone/metering zone/die=175/200/220/220 °C.

### PO Layer (D): PP

Extruder: single-screw extruder (GT-32-A, Research Laboratory of Plastics Technology Co., Ltd.)
Screw: diameter=32 mmφ, L/D=28, full flight screw
Extrusion temperature: feeding zone/compression zone/metering zone/die=175/200/220/220 °C.
Die: 300-mm-wide coat hanger die for three layers each selected from three types (produced by Research Laboratory of Plastics Technology Co., Ltd.)

The obtained unoriented multilayer film was oriented by 3.2 times in the longitudinal direction and by 3.0 times in the lateral direction at 160 °C by using tenter-type simultaneous biaxial orientation equipment to obtain a biaxially oriented multilayer film having a configuration of EVOH-2/Ad/PP=1 μm/1 μm/18 μm.

Aluminum was vacuum-deposited on the barrier layer (A) of the obtained biaxially oriented multilayer film by the same procedure as in Example 1 to produce a vapor-deposited film (vapor-deposited aluminum layer/EVOH-2/Ad/PP=40 nm/1 μm/1 μm/18 μm) in which a vapor-deposited aluminum layer having an average thickness of 40 nm was formed on the barrier layer (A). With regard to the obtained vapor-deposited film, the molar ratio (O/Al) of an oxygen element to an aluminum element in the vapor-deposited aluminum layer (B) was measured according to the method described above in Section (1) of Evaluation Method 1. The results are shown in Table 5.

Adhesive layers were provided in the following manner: one face of the OPP and one face of the CPP50 were each coated with a two-component urethane adhesive (“TAKELAC (trademark) A-520” and “TAKENATE (trademark) A-50,” produced by Mitsui Chemicals, Inc.) such that the average thickness of the adhesive after drying was 2 μm, and drying was performed. After that, the OPP (PO layer (E1)) provided with the adhesive layer was laminated on the vapor-deposited aluminum layer side of the vapor-deposited film produced in the above manner, and the CPP50 (PO layer (C2)) provided with the adhesive layer was laminated on the PO layer (D) side, and the resulting structure was subjected to lamination while performing nip-roll pressure bonding at 70 °C. After that, aging was performed at 40 °C for 4 days to obtain a multilayer structure (OPP/tie/Al/EVOH-2/Ad/PP/tie/CPP=20 μm/2 μm/40 nm/1 μm/1 μm/18 μm/2 μm/50 μm (tie means the adhesive layer, and Al means the vapor-deposited aluminum layer)). With regard to the obtained multilayer structure, the OTR before the storage test was evaluated according to the method described above in Section (6) of Evaluation Method 3. The results are shown in Table 5.

The obtained multilayer structure was cut to form two cover materials each having a size of 15 cm (wide)×20 cm (long), the cover materials were superimposed such that the CPP layers were the inner faces, and three sides were heat-sealed to a width of 10 mm to produce a three-sided bag as a packaging bag. Into the packaging bag, 50 g of tomato ketchup produced by Kagome Co., Ltd. was put, a 15-cm-long portion (remaining one side which had not been heat-sealed) was heat-sealed to a width of 10 mm by using a vacuum packaging machine VAC-STAR 2500GSL, produced by Frimark GmbH, to produce a 15 cm (wide)×15 cm (long) pouch in which the 50 g of ketchup was vacuum-packaged. With regard to the obtained pouch, the OTR and the appearance after the storage test were evaluated according to the method described above in Section (7) of Evaluation Method 3. The results are shown in Table 5.

### Examples 17 to 22 and Comparative Examples 11 to 13

Biaxially oriented multilayer films, vapor-deposited films, multilayer structures, and pouches were produced and evaluated by the same procedures as above, except that at the time of producing the vapor-deposited film in Example 16, the oxygen supply rate was changed as in Table 4. The results are shown in Table 5.

### Example 23

A biaxially oriented multilayer film, a vapor-deposited film, a multilayer structure, and a pouch were produced and evaluated by the same procedure as in Example 20, except that at the time of producing the multilayer structure, the PO layer (E2) (CPP50) was not laminated. The results are shown in Table 5.

### Example 24

A biaxially oriented multilayer film, a vapor-deposited film, a multilayer structure, and a pouch were produced and evaluated by the same procedure as in Example 17, except that at the time of producing the multilayer structure, the PO layer (E2) (CPP50) was not laminated. The results are shown in Table 5.

### Example 25

A biaxially oriented multilayer film, a vapor-deposited film, a multilayer structure, and a pouch were produced and evaluated by the same procedure as in Example 23, except that the transport velocity of the biaxially oriented multilayer film during the vapor deposition was changed to 75 m/min and the vapor deposition was performed such that the average thickness of the vapor-deposited aluminum layer was 80 nm. The results are shown in Table 5.

### Example 26

A biaxially oriented multilayer film, a vapor-deposited film, a multilayer structure, and a pouch were produced and evaluated by the same procedure as in Example 24, except that the transport velocity of the biaxially oriented multilayer film during the vapor deposition was changed to 75 m/min and the vapor deposition was performed such that the average thickness of the vapor-deposited aluminum layer was 80 nm. The results are shown in Table 5.

### Example 27

A biaxially oriented multilayer film, a vapor-deposited film, a multilayer structure, and a pouch were produced and evaluated by the same procedure as in Example 16, except that at the time of producing the multilayer structure, the CPP30 was used as the PO layer (E2) instead of the CPP50. The results are shown in Table 5.

### Example 28

An unoriented multilayer film was produced such that the average thickness of each layer was adjusted to EVOH-2/Ad/PP=30 μm/30 μm/108 μm, the obtained unoriented multilayer film was heated to 160 °C and then oriented by 6 times in the longitudinal direction (MD direction) by a roll-type orientation machine to produce a uniaxially oriented multilayer film (EVOH-2/Ad/PP=5 μm/5 μm/18 μm). The obtained uniaxial multilayer film was directly used as a vapor deposition base. Except for the above points, a vapor-deposited film, a multilayer structure, and a pouch were produced and evaluated by the same procedure as in Example 27. The results are shown in Table 5.

### Example 29

An unoriented multilayer film, a vapor-deposited film, a multilayer structure, and a pouch were produced and evaluated by the same procedure as in Example 27, except that the unoriented multilayer film (EVOH-2/Ad/PP=5 μm/5 μm/18 μm) was produced such that the average thicknesses of the barrier layer (A), the adhesive resin layer (C), and the PO layer (D) had average thicknesses shown in Table 3 and the obtained unoriented multilayer film was directly used as a vapor deposition base. The results are shown in Table 5.

### Example 30

An unoriented multilayer film, a vapor-deposited film, a multilayer structure, and a pouch were produced and evaluated by the same procedure as in Example 29, except that the EVOH-3 was used as the barrier layer (A). The results are shown in Table 5.

### Example 31

A multilayer structure and a pouch were produced and evaluated by the same procedure as in Example 30, except that the vapor-deposited film produced in Example 10 was used as a vapor-deposited film. It is to be noted that the CPP30 was laminated on the OPET side. The results are shown in Table 5.

### Comparative Example 14

A multilayer structure and a pouch were produced and evaluated by the same procedure as in Example 30, except that the vapor-deposited film produced in Comparative Example 4 was used as a vapor-deposited film. It is to be noted that the CPP30 was laminated on the OPET side. The results are shown in Table 5.

TABLE 4

| | Multilayer structure | | | | | | | | | | | | | |
|---|---|---|---|---|---|---|---|---|---|---|---|---|---|---|
| | vapor-deposited film | | | | | | | | | | | | | |
| | | | vapor-deposited | | | | | | | PO layer (E) | | | | |
| | barrier layer (A) | | Al layer (B) | | adhesive resin layer (C) | | PO layer (D) | | | PO layer (E1) | | PO layer (E2) | | |
| | | average | average | oxygen | | average | | average | | | average | | average | |
| | type | thickness | thickness | supply rate | type | thickness | type | thickness | orientation | type | thickness | type | thickness | layer |
| Unit | — | μm | nm | mL/min | — | μm | — | μm | — | — | μm | — | μm | configuration |
| Example 16 | EVOH-2 | 1 | 40 | 80 | Ad | 1 | PP | 18 | biaxially | OPP | 20 | CPP50 | 50 | OPP/tie/Al/EVOH-2/AD/PP/ |
| | | | | | | | | | oriented | | | | | tie/CPP |
| Example 17 | EVOH-2 | 1 | 40 | 100 | Ad | 1 | PP | 18 | biaxially | OPP | 20 | CPP50 | 50 | OPP/tie/Al/EVOH-2/AD/PP/ |
| | | | | | | | | | oriented | | | | | tie/CPP |
| Example 18 | EVOH-2 | 1 | 40 | 130 | Ad | 1 | PP | 18 | biaxially | OPP | 20 | CPP50 | 50 | OPP/tie/Al/EVOH-2/AD/PP/ |
| | | | | | | | | | oriented | | | | | tie/CPP |
| Example 19 | EVOH-2 | 1 | 40 | 160 | Ad | 1 | PP | 18 | biaxially | OPP | 20 | CPP50 | 50 | OPP/tie/Al/EVOH-2/AD/PP/ |
| | | | | | | | | | oriented | | | | | tie/CPP |
| Example 20 | EVOH-2 | 1 | 40 | 70 | Ad | 1 | PP | 18 | biaxially | OPP | 20 | CPP50 | 50 | OPP/tie/Al/EVOH-2/AD/PP/ |
| | | | | | | | | | oriented | | | | | tie/CPP |
| Example 21 | EVOH-2 | 1 | 40 | 50 | Ad | 1 | PP | 18 | biaxially | OPP | 20 | CPP50 | 50 | OPP/tie/Al/EVOH-2/AD/PP/ |
| | | | | | | | | | oriented | | | | | tie/CPP |
| Example 22 | EVOH-2 | 1 | 40 | 30 | Ad | 1 | PP | 18 | biaxially | OPP | 20 | CPP50 | 50 | OPP/tie/Al/EVOH-2/AD/PP/ |
| | | | | | | | | | oriented | | | | | tie/CPP |
| Example 23 | EVOH-2 | 1 | 40 | 70 | Ad | 1 | PP | 18 | biaxially | OPP | 20 | — | — | OPP/tie/Al/EVOH-2/AD/PP |
| | | | | | | | | | oriented | | | | | |
| Example 24 | EVOH-2 | 1 | 40 | 100 | Ad | 1 | PP | 18 | biaxially | OPP | 20 | — | — | OPP/tie/Al/EVOH-2/AD/PP |
| | | | | | | | | | oriented | | | | | |
| Example 25 | EVOH-2 | 1 | 80 | 70 | Ad | 1 | PP | 18 | biaxially | OPP | 20 | — | — | OPP/tie/Al/EVOH-2/AD/PP |
| | | | | | | | | | oriented | | | | | |
| Example 26 | EVOH-2 | 1 | 80 | 100 | Ad | 1 | PP | 18 | biaxially | OPP | 20 | — | — | OPP/tie/Al/EVOH-2/AD/PP |
| | | | | | | | | | oriented | | | | | |
| Example 27 | EVOH-2 | 1 | 40 | 80 | Ad | 1 | PP | 18 | biaxially | OPP | 20 | CPP30 | 30 | OPP/tie/Al/EVOH-2/AD/PP/ |
| | | | | | | | | | oriented | | | | | tie/CPP |
| Example 28 | EVOH-2 | 5 | 40 | 80 | Ad | 5 | PP | 18 | biaxially | OPP | 20 | CPP30 | 30 | OPP/tie/Al/EVOH-2/AD/PP/ |
| | | | | | | | | | oriented | | | | | tie/CPP |
| Example 29 | EVOH-2 | 5 | 40 | 80 | Ad | 5 | PP | 18 | unoriented | OPP | 20 | CPP30 | 30 | OPP/tie/Al/EVOH-2/AD/PP/ |
| | | | | | | | | | | | | | | tie/CPP |
| Example 30 | EVOH-3 | 5 | 40 | 80 | Ad | 5 | PP | 18 | unoriented | OPP | 20 | CPP30 | 30 | OPP/tie/Al/EVOH-3/AD/PP/ |
| | | | | | | | | | | | | | | tie/CPP |
| Example 31 | OPET | 1 | 40 | 80 | — | — | — | — | — | OPP | 20 | CPP30 | 30 | OPP/tie/Al/OPET/tie/CPP |
| Comparative | EVOH-2 | 1 | 40 | 200 | Ad | 1 | PP | 18 | biaxially | OPP | 20 | CPP30 | 30 | OPP/tie/Al/EVOH-2/AD/PP/ |
| Example 11 | | | | | | | | | oriented | | | | | tie/CPP |
| Comparative | EVOH-2 | 1 | 40 | 10 | Ad | 1 | PP | 18 | biaxially | OPP | 20 | CPP30 | 30 | OPP/tie/Al/EVOH-2/AD/PP/ |
| Example 12 | | | | | | | | | oriented | | | | | tie/CPP |
| Comparative | EVOH-2 | 1 | 40 | 0 | Ad | 1 | PP | 18 | biaxially | OPP | 20 | CPP30 | 30 | OPP/tie/Al/EVOH-2/AD/PP/ |
| Example 13 | | | | | | | | | oriented | | | | | tie/CPP |
| Comparative | OPET | 1 | 40 | 0 | — | — | — | — | — | OPP | 20 | CPP30 | 30 | OPP/tie/Al/OPET/tie/CPP |
| Example 14 | | | | | | | | | | | | | | |

TABLE 5

| | Evaluation | | | | | |
|---|---|---|---|---|---|---|
| | molar ratio (O/A1) of vapor- | | | OTR | | |
| | deposited Al layer (B) | | | before | after | |
| | B1 | B2 | B3 | storage | storage | |
| | (O/A1)_{MAX} | (O/A1)_{MIN} | (O/A1)_{S} | test | test | appearance |
| Unit | — | — | — | — | — | — |
| Example 16 | 1.31 | 0.02 | 1.58 | A | A | A |
| Example 17 | 1.42 | 0.02 | 1.53 | A | A | A |
| Example 18 | 1.78 | 0.03 | 1.72 | A | B | A |
| Example 19 | 1.95 | 0.03 | 1.82 | B | D | D |
| Example 20 | 1.13 | 0.02 | 1.51 | A | A | A |
| Example 21 | 0.84 | 0.03 | 1.48 | B | C | C |
| Example 22 | 0.57 | 0.04 | 1.41 | B | C | C |
| Example 23 | 1.13 | 0.03 | 1.47 | A | D | D |
| Example 24 | 1.42 | 0.03 | 1.46 | A | C | C |
| Example 25 | 1.13 | 0.03 | 1.33 | A | B | B |
| Example 26 | 1.36 | 0.03 | 1.51 | A | A | A |
| Example 27 | 1.31 | 0.02 | 1.58 | A | B | B |
| Example 28 | 1.25 | 0.03 | 1.51 | B | C | C |
| Example 29 | 1.32 | 0.02 | 1.47 | C | D | D |
| Example 30 | 1.29 | 0.02 | 1.34 | B | C | C |
| Example 31 | 1.36 | 0.02 | 1.64 | C | D | D |
| Comparative | 2.13 | 0.03 | 1.24 | C | E | E |
| Example 11 | | | | | | |
| Comparative | 0.27 | 0.03 | 1.32 | B | E | E |
| Example 12 | | | | | | |
| Comparative | 0.13 | 0.01 | 1.32 | B | E | E |
| Example 13 | | | | | | |
| Comparative | 0.08 | 0.03 | 1.59 | C | E | E |
| Example 14 | | | | | | |

As shown in Table 1, the vapor-deposited films of Examples 1 to 10 had favorable bending resistance and storage stability. As shown in Tables 2 and 3, the vacuum insulators obtained from the respective multilayer structures of Examples 11 to 15 had favorable heat insulation performance, bending resistance, and storage stability. As shown in Tables 4 and 5, the pouches obtained from the respective multilayer structures of Examples 16 to 31 had favorable gas barrier properties both before and after the storage, and the appearance after the storage was also favorable. Furthermore, it could be confirmed that during the aluminum vapor deposition, by blowing a small amount of oxygen onto the vapor deposition base (barrier layer (A)) and by adjusting the oxygen supply rate, the maximum value (O/Al)_{MAX} of the molar ratio of an oxygen element to an aluminum element in the aluminum oxide layer (B1) could be controlled. It is to be noted that in each of Examples 23 to 26, which did not include the CPP layer, the appearance of the pouch was deteriorated when the heat sealing was performed to produce the pouch.

### EXPLANATION OF REFERENCE SYMBOLS

10: Vapor-deposited film
A: Barrier layer (A)
B: Vapor-deposited aluminum layer (B)
B1: Aluminum oxide layer (B1)
B2: Aluminum layer (B2)
B3: Aluminum oxide layer (B3)
S: Face of the vapor-deposited aluminum layer (B), the face being opposite to the face in contact with the barrier layer (A)

1. A vapor-deposited film comprising:
a barrier layer (A) made of a resin; and
a vapor-deposited aluminum layer (B) directly laminated on the barrier layer (A) and having an average thickness of 30 nm or more and 100 nm or less,
wherein
the vapor-deposited aluminum layer (B) comprises an aluminum oxide layer (B1) and an aluminum layer (B2) sequentially arranged in this order from a face in contact with the barrier layer (A),
in an elemental analysis in a depth direction of the aluminum oxide layer (B1), a maximum value (O/Al)_{MAX} of a molar ratio of an oxygen element to an aluminum element, the molar ratio being measured using a scanning x-ray photoelectron spectrometer, is 0.5 or more and 2.0 or less, and
in a depth-direction analysis of the aluminum layer (B2), a minimum value (O/Al)_{MIN} of a molar ratio of an oxygen element to an aluminum element, the molar ratio being measured using a scanning x-ray photoelectron spectrometer, is less than 0.5.

2. The vapor-deposited film according to claim 1,
wherein
the vapor-deposited aluminum layer (B) comprises an aluminum oxide layer (B3) comprising a face(S) opposite to the face in contact with the barrier layer (A), and
in an elemental analysis of the face(S), a molar ratio (O/Al) s of an oxygen element to an aluminum element, the molar ratio being measured using a scanning x-ray photoelectron spectrometer, is 0.5 or more and 2.0 or less.

3. The vapor-deposited film according to claim 1, wherein the barrier layer (A) comprises, as a principal component, at least one selected from the group consisting of a vinyl alcohol polymer and a polyester resin.

4. The vapor-deposited film according to claim 1, wherein the barrier layer (A) is biaxially oriented.

5. The vapor-deposited film according to claim 1, wherein an average thickness of the barrier layer (A) is 0.1 μm or more and 20 μm or less.

6. The vapor-deposited film according to claim 1, wherein an average thickness of the vapor-deposited aluminum layer (B) is 55 nm or more and 90 nm or less.

7. The vapor-deposited film according to claim 1, further comprising a polyolefin layer (D) laminated on a face of the barrier layer (A) with an adhesive resin layer (C) interposed therebetween, the face being opposite to the vapor-deposited aluminum layer (B).

8. The vapor-deposited film according to claim 7, wherein the barrier layer (A), the adhesive resin layer (C), and the polyolefin layer (D) are at least uniaxially oriented.

9. A multilayer structure comprising:
the vapor-deposited film according to claim 7; and
a polyolefin layer (E) laminated on at least one face of the vapor-deposited film directly or with another layer interposed therebetween.

10. The multilayer structure according to claim 9, wherein polyolefin layers (E) are respectively laminated on both faces of the vapor-deposited film directly or with another layer interposed therebetween, and the polyolefin layers (E) comprise the same type of resin as a principal component.

11. The multilayer structure according to claim 9, wherein a thickness percentage of the barrier layer (A) with respect to a total thickness of the multilayer structure is 5% or less.

12. A multilayer structure comprising:
the vapor-deposited film according to claim 1; and
a polyolefin layer (E) laminated on the vapor-deposited film directly or with another layer interposed therebetween.

13. The multilayer structure according to claim 12, further comprising an other vapor-deposited film laminated on the vapor-deposited film directly or with another layer interposed therebetween,
wherein the other vapor-deposited film comprises: a barrier layer (a) made of a resin; and a vapor-deposited aluminum layer (b) directly laminated on the barrier layer (a) and having an average thickness of 30 nm or more and 100 nm or less.

14. The multilayer structure according to claim 13,
wherein
the vapor-deposited aluminum layer (b) comprises an aluminum oxide layer (b1) and an aluminum layer (b2) sequentially arranged in this order from a face in contact with the barrier layer (a),
in an elemental analysis in a depth direction of the aluminum oxide layer (b1), a maximum value (O/Al)_{MAX} of a molar ratio of an oxygen element to an aluminum element, the molar ratio being measured using a scanning x-ray photoelectron spectrometer, is 0.5 or more and 2.0 or less, and
in a depth-direction analysis of the aluminum layer (b2), a minimum value (O/Al)_{MIN} of a molar ratio of an oxygen element to an aluminum element, the molar ratio being measured using a scanning x-ray photoelectron spectrometer, is less than 0.5.

15. The multilayer structure according to claim 12, further comprising a polyamide layer (F) laminated on the vapor-deposited film directly or with another layer interposed therebetween.

16. A packaging material comprising the vapor-deposited film according to any one of claims 1 to 8 or the multilayer structure according to claim 9.

17. A vacuum packaging bag comprising a packaging bag formed from the packaging material according to claim 16,
wherein an inside of the packaging bag has a reduced pressure.

18. A vacuum insulator comprising:
the vacuum packaging bag according to claim 17; and
a core material disposed inside the vacuum packaging bag.
